(19) United States
(12) Patent Application Publication
(10) Pub. No.: US 2026/0026009 A1
(43) Pub. Date: Jan. 22, 2026

(54) 3D FERROELECTRIC MEMORY DEVICES

(71) Applicant: Samsung Electronics Co., Ltd., Suwon-si (KR)

(72) Inventors: Yeonjin Lee, Suwon-si (KR); Haewook Jeong, Suwon-si (KR)

(21) Appl. No.: 19/248,222

(22) Filed: Jun. 24, 2025

(30) Foreign Application Priority Data
Jul. 19, 2024 (KR) 10-2024-0095562

(51) Int. Cl. H10B 53/20; H10B 53/30

(52) U.S. Cl. CPC H10B 53/20; H10B 53/30

(57) ABSTRACT

A three-dimensional ferroelectric memory device is provided. The three-dimensional ferroelectric memory device includes a substrate; a plurality of bit lines extending in a first direction on the substrate and spaced apart from each other; first and second block selection lines extending in the second direction over the plurality of bit lines; a first word line that overlaps at least part of the first block selection line; a second word line that overlaps at least part of the second block selection line; a first channel extending in a third direction on a first bit line; a second channel extending in the third direction on the first bit line; a ferroelectric pattern arranged between the first channel and the second channel; and first and second capacitor electrodes arranged adjacent to the ferroelectric pattern and separated in the first direction by a separation pattern.

### CROSS-REFERENCE TO RELATED APPLICATION

This application claims priority to and the benefit of Korean Patent Application No. 10-2024-0095562 filed in the Korean Intellectual Property Office on Jul. 19, 2024, the entire contents of which are incorporated herein by reference.

### BACKGROUND

Ferroelectric Random Access Memory: (FeRAM) devices or Ferroelectric Field Effect Transistor: (FeFET) devices are used as memory devices that have a simple structure compared to DRAM devices but have non-volatile characteristics like flash memory devices. Recently, a three-dimensional FeRAM or a three-dimensional FeFET is being developed to implement high integration, but an effective implementation method is required.

### SUMMARY

An implementation provides a three-dimensional ferroelectric memory device with improved electric characteristics and integration.

An implementation provides a manufacturing method of a three-dimensional ferroelectric memory device with easily improved electric characteristics.

According to a disclosed implementation, a three-dimensional ferroelectric memory device including a substrate; a plurality of bit lines extending in a first direction on the substrate and spaced apart from each other in a second direction intersecting the first direction; first and second block selection lines extending in the second direction over the plurality of bit lines and spaced apart from each other in the first direction; a first word line that overlaps at least part of the first block selection line in a third direction orthogonal with the first direction and the second direction, where the first word line extends in the second direction; a second word line that overlaps at least part of the second block selection line in the third direction, is separated from the first word line in the first direction, and extends in the second direction; a first channel extending in the third direction on the first bit line among the plurality of bit lines and positioned adjacent to the first block selection line and the first word line; a second channel extending in the third direction on the first bit line and positioned adjacent to the second block selection line and the second word line; a ferroelectric pattern arranged between the first channel and the second channel; and first and second capacitor electrodes arranged adjacent to the ferroelectric pattern in the third direction between the first channel and the second channel, and separated in the first direction by a separation pattern is provided.

According to a disclosed implementation, a three-dimensional ferroelectric memory device including a substrate; a plurality of bit lines extending in a first direction on the substrate and spaced apart from each other in a second direction intersecting the first direction; first and second block selection lines extending in the second direction over the plurality of bit lines and spaced apart from each other in the first direction; a first word line that overlaps at least part of the first block selection line in a third direction orthogonal with the first direction and the second direction and where the first word line extends in the second direction; a second word line that overlaps at least part of the second block selection line in the third direction, is separated from the first word line in the first direction, and extends in the second direction; a first channel extending in a third direction perpendicular to the substrate on the first bit line among the plurality of bit lines and positioned adjacent to the first block selection line and the first word line; a second channel extending in the third direction on the first bit line and positioned adjacent to the second block selection line and the second word line; a first capacitor electrode and a second capacitor electrode both arranged between the first channel and the second channel, the first capacitor electrode being separated from the second capacitor electrode in the first direction; and a ferroelectric pattern in contact with the first and second capacitor electrodes between the first channel and the second channel is provided.

According to a disclosed implementation, a three-dimensional ferroelectric memory device including a substrate; a first bit line extending in a first direction on the substrate; first and second block selection lines extending in a second direction intersecting the first direction over the first bit line, connected to the first bit line, and spaced apart from each other in the first direction; a first word line that overlaps at least part of the first block selection line in a third direction orthogonal with the first direction and the second direction and where the first word line extends in the second direction; a second word line that overlaps at least a portion of the second block selection line in the third direction, is separated from the first word line in the first direction, and extends in the second direction; a first cell string including a first block selection transistor controlled by the first block selection line, a first transistor controlled by the first word line, and a first capacitor connected in parallel to the first transistor; and a second cell string including a second block selection transistor controlled by the second block selection line, a second transistor controlled by the second word line, and a second capacitor connected in parallel to the second transistor is provided, wherein the first and second capacitors share a ferroelectric pattern.

According to a disclosed implementation, a three-dimensional ferroelectric memory device including a substrate; a plurality of bit lines extending in a first direction on the substrate and spaced apart from each other in a second direction intersecting the first direction; first to third second block selection lines extending in the second direction over the plurality of bit lines and spaced apart from each other in the first direction; a first word line that overlaps at least part of the first block selection line in a third direction orthogonal with the first direction and the second direction and where the first word line extends in the second direction; a second word line that overlaps at least part of the second block selection line in the third direction, is separated from the first word line in the first direction, and extends in the second direction; a third word line that overlaps at least part of the third block selection line in the third direction, is separated from the first word line in the first direction, and extends in the second direction; a first channel extending in a third direction perpendicular to the substrate on the first bit line among the plurality of bit lines and positioned adjacent to the first block selection line and the first word line; a second channel extending in the third direction on the first bit line and positioned adjacent to the second block selection line and the second word line; a ferroelectric pattern arranged between the first channel and the second channel; and a first capacitor electrode and a second capacitor electrode both arranged adjacent to the ferroelectric pattern in the third direction and between the first channel and the second channel, wherein the first capacitor electrode and the second capacitor electrode are separated from each other in the first direction, wherein the first block selection line is between the second block selection line and the third block selection line in the first direction, and a distance between the first block selection line and the second block selection line and a distance between the first block selection line and the third block selection line are different.

### BRIEF DESCRIPTION OF THE DRAWINGS

FIG. 1 is a perspective view showing an example three-dimensional ferroelectric memory device.

FIG. 2 is a perspective view showing a cell region of an example three-dimensional ferroelectric memory device.

FIG. 3 is a top plan view showing a cell region of an example three-dimensional ferroelectric memory device.

FIG. 4 is a cross-sectional view taken along a line A-A′ of FIG. 3.

FIG. 5 is a cross-sectional view taken along a line B-B′ of FIG. 3.

FIG. 6 is an enlarged view of a region S of FIG. 4.

FIG. 7 is a circuit diagram showing an example memory cell string included in a three-dimensional ferroelectric memory device.

FIG. 8 to FIG. 10 are views for explaining a program operation of a memory cell included in an example three-dimensional ferroelectric memory device.

FIG. 11 and FIG. 12 are views for explaining an operation of a memory cell string included in an example three-dimensional ferroelectric memory device.

FIG. 13 is a perspective view showing a cell region of an example three-dimensional ferroelectric memory device.

FIG. 14 is a top plan view showing a cell region of an example three-dimensional ferroelectric memory device.

FIG. 15 is a cross-sectional view taken along a line B-B′ of FIG. 14.

FIG. 16 is a perspective view showing a cell region of an example three-dimensional ferroelectric memory device.

FIG. 17 is a top plan view showing a cell region of an example three-dimensional ferroelectric memory device.

FIG. 18 is a cross-sectional view taken along a line A-A′ of FIG. 17.

FIG. 19 is a circuit diagram showing a memory cell string included in an example three-dimensional ferroelectric memory device.

FIG. 20 to FIG. 42 are views for explaining a manufacturing method of an example three-dimensional ferroelectric memory.

FIG. 43 is a perspective view showing a cell region of an example three-dimensional ferroelectric memory device.

FIG. 44 is a top plan view showing a cell region of an example three-dimensional ferroelectric memory device.

FIG. 45 is a cross-sectional view taken along a line A-A′ of FIG. 44.

FIG. 46 is a cross-sectional view taken along a line B-B′ of FIG. 44.

FIG. 47 to FIG. 61 are views for explaining a manufacturing method of an example three-dimensional ferroelectric memory device.

FIG. 62 is a block diagram showing an example electronic device.

### DETAILED DESCRIPTION

The present disclosure will be described more fully hereinafter with reference to the accompanying drawings, in which exemplary implementations of the disclosure are shown. As those skilled in the art would realize, the described implementations may be modified in various different ways, all without departing from the spirit or scope of the present disclosure.

In order to clearly explain the present disclosure, a portion that is not directly related to the present disclosure was omitted, and the same reference numerals are attached to the same or similar constituent elements through the entire specification.

In addition, unless explicitly described to the contrary, the word “comprise”, and variations such as “comprises” or “comprising”, will be understood to imply the inclusion of stated elements but not the exclusion of any other elements.

Also, throughout the specification, when it is said that ‘one component is placed adjacent to another component’, it means that one component and another component are placed next to each other so that no component that is identical or similar to one component between the one component and another component, or one component and another component are in contact with each other. For example, ‘X’ being placed adjacent to ‘Y’ includes ‘X’ and ‘Y’ being adjacent so that no component identical or similar to ‘X’ is placed between ‘X’ and ‘Y’, or ‘X’ and ‘Y’ are in contact with each other

Additionally, a specific number stated in a claim, even if explicitly cited within the claim, should not be construed as limiting the specific number in a claim where such citation does not exist. For example, to aid understanding, subsequent dependent claims could include the phrases ‘at least one’ and ‘one or more’. However, the use of such a phrase should not be understood as a limitation described by the unclear article ‘one’ for the sake of one example.

Additionally, when conventions such as ‘at least one of A, B, or C’ are used, these phrases will be well understood by those skilled in the art. (i.e., ‘a system including at least one of A, B, or C’ includes the meaning of A alone, B alone, C alone, A and B, A and C, B and C, and/or A, B, and C together, but it is not limited to any one concept). Also, in detailed descriptions or claims or drawings, letters and/or phrases including two or more separated selectable terms should be considered as possible to include one, or either, or both terms. For example, the phrase ‘A or B’ should be understood as including the possibilities ‘A’, or ‘B’ or ‘A and B’.

Terms such as “module,” “unit,” and “part” used in this document refer to a component that performs at least one function or operation, and these components may be implemented as a hardware or a software, or as a combination of hardware and software.

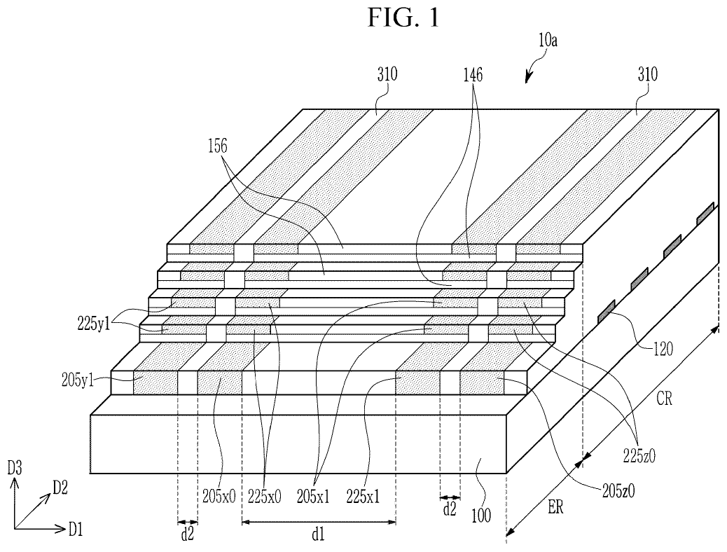

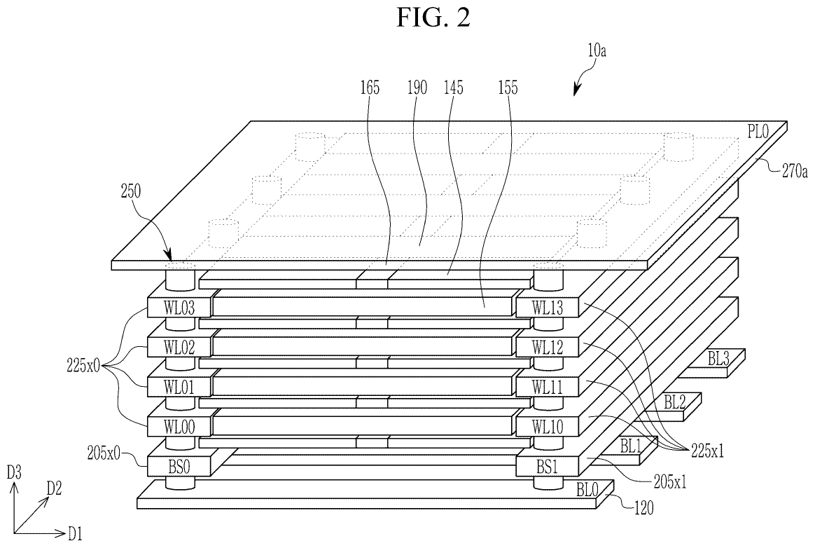

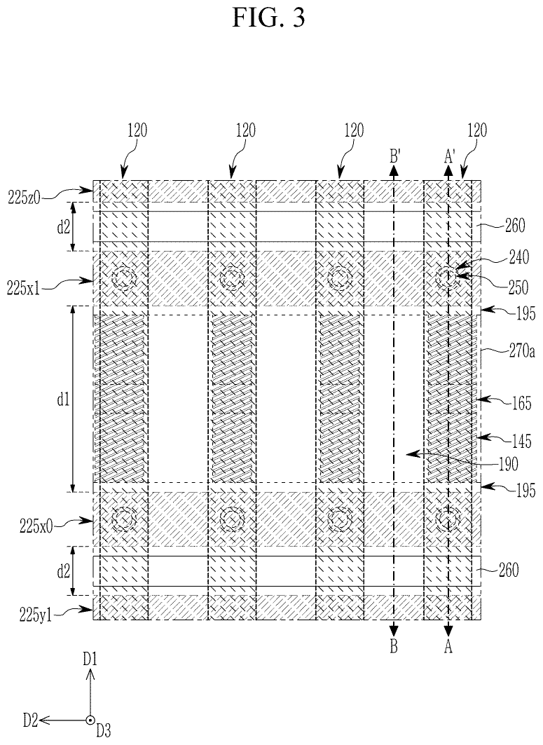

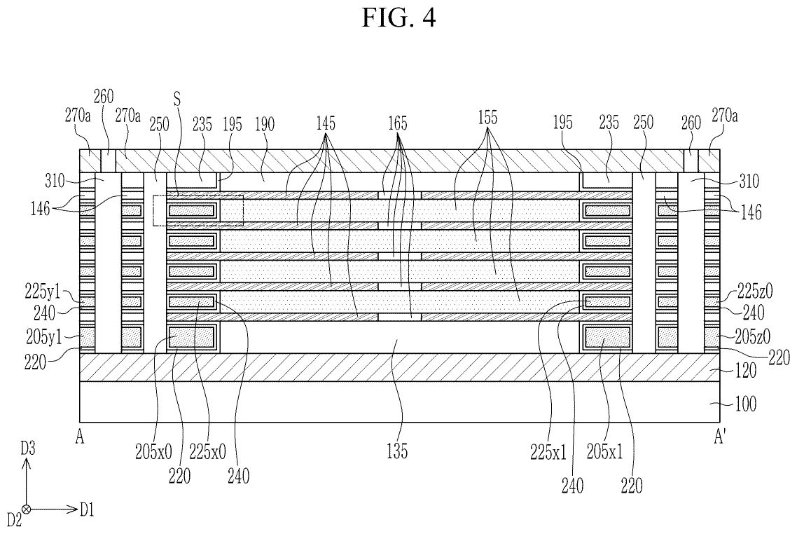

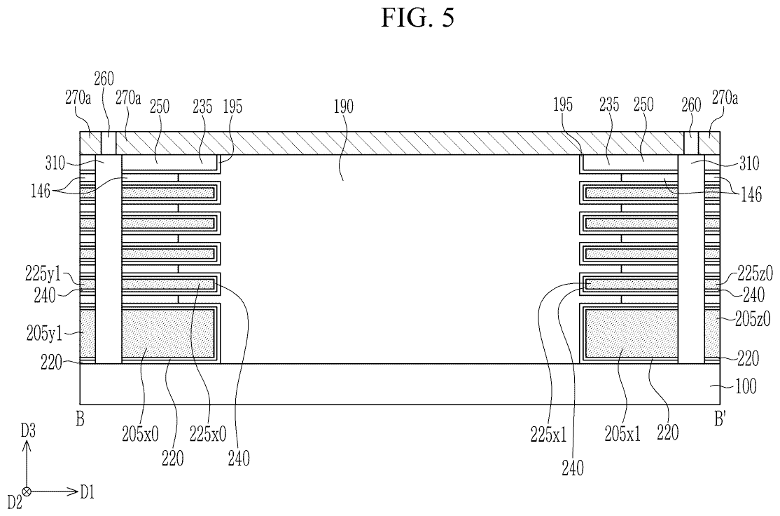

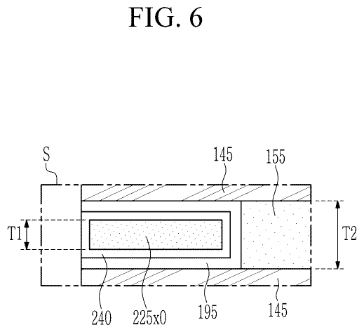

FIG. 1 is a perspective view showing a three-dimensional ferroelectric memory device according to one or more implementations. FIG. 2 is a perspective view showing the cell region of a three-dimensional ferroelectric memory device according to one or more implementations. FIG. 3 is a top plan view showing a cell region of a three-dimensional ferroelectric memory device according to one or more implementations. FIG. 4 is a cross-sectional view taken along a line A-A′ of FIG. 3. FIG. 5 is a cross-sectional view taken along a line B-B′ of FIG. 3. FIG. 6 is an enlarged view of a region S of FIG. 4. Specifically, FIG. 3 is a top plan view showing a part of a cell region CR of a three-dimensional ferroelectric memory device 10a.

Referring to FIG. 1 to FIG. 6, the three-dimensional ferroelectric memory device 10a may include a cell region CR and an extending region ER. The cell region CR may include a bit line 120 extending in a first direction D1 on the substrate 100. The bit line 120 may include a plurality of bit lines spaced apart from each other in a second direction D2 in the cell region CR.

The cell region CR and the extending region ER may include a plurality of conductive patterns 205x0, 205x1, 205y1, 205z0, 225x0, 225x1, 225y1, and 225z0 extending in the second direction D2 on the substrate 100 and the plurality of bit lines 120. The cell region CR may include a memory cell string connected to the plurality of conductive patterns 205x0, 205x1, 205y1, 205z0, 225x0, 225x1, 225y1, and 225z0 and the bit line 120, and extending in a third direction D3. According to one or more implementations, the memory cell string may include a plurality of memory cells including transistors and ferroelectric capacitors. In the present disclosure, the third direction D3 may be a direction perpendicular to the substrate 100.

The first/first conductive pattern 205x0 and the first/second conductive pattern 225x0 may be arranged to be spaced apart from each other in the third direction D3 in the extending region ER, and at least some of them may be arranged to overlap each other in a flat area. In the flat area may refer to along the third direction. The third direction is orthogonal to the first direction and the second direction. For example, the first/first conductive pattern 205x0 and the first/second conductive pattern 225x0 may be partially overlapped along the third direction, and overlapping surfaces can be perpendicular to the third direction and/or parallel to a top surface of the substrate. As the first/first conductive pattern 205x0 and the first/second conductive pattern 225x0 are positioned higher in the third direction D3 in the extending region ER, the length by which the first/first conductive pattern 205x0 and the first/second conductive pattern 225x0 extend in the second direction D2 may be shortened. In the extending region ER, the first/first conductive pattern 205x0 and the first/second conductive pattern 225x0 may be implemented as a step-like wire structure. Additionally, the first insulating pattern 146, which insulates between the first/first conductive pattern 205x0 and the first/second conductive pattern 225x0, may be implemented as a step-like structure in the extending region ER.

The second/first conductive pattern 205x1 and the second/second conductive pattern 225x1 may be arranged to be spaced apart from each other in the third direction D3 in the extending region ER, and at least some of them may be arranged to overlap each other in a flat area. As the second/first conductive pattern 205x1 and the second/second conductive pattern 225x1 are positioned higher in the third direction D3 in the extending region ER, the length by which the second/first conductive pattern 205x1 and the second/second conductive pattern 225x1 extend in the second direction D2 may be shortened. In the extending region ER, the second/first conductive pattern 205x1 and the second/second conductive pattern 225x1 may be implemented as a step-like wire structure. Additionally, the first insulating pattern 146, which insulates between the second/first conductive pattern 205x1 and the second/second conductive pattern 225x1, may be implemented as a step-like structure in the extending region ER.

The third/first conductive pattern 205y1 and the third/second conductive pattern 225y1 may be arranged to be spaced apart from each other in the third direction D3 in the extending region ER, and at least some of them may be arranged to overlap each other in a flat area. As the third/first conductive pattern 205y1 and the third/second conductive pattern 225y1 are positioned higher in the third direction D3 in the extending region ER, the length by which the third/first conductive pattern 205y1 and the third/second conductive pattern 225y1 extend in the second direction D2 may be shortened. In the extending region ER, the third/first conductive pattern 205y1 and the third/second conductive pattern 225y1 may be implemented as a step-like wire structure. Additionally, the first insulating pattern 146, which insulates between the third/first conductive pattern 205y1 and the third/second conductive pattern 225y1, may be implemented as a step-like structure in the extending region ER.

The fourth/first conductive pattern 205z0 and the fourth/second conductive pattern 225z0 may be arranged to be spaced apart from each other in the third direction D3 in the extending region ER, and at least some of them may be arranged to overlap each other in a flat area. As the fourth/first conductive pattern 205z0 and the fourth/second conductive pattern 225z0 are positioned higher in the third direction D3 in the extending region ER, the length by which the fourth/first conductive pattern 205z0 and the fourth/second conductive pattern 225z0 extend in the second direction D2 may be shortened. In the extending region ER, the fourth/first conductive pattern 205z0 and the fourth/second conductive pattern 225z0 may be implemented as a step-like wire structure. Additionally, the first insulating pattern 146, which insulates between the fourth/first conductive pattern 205z0 and the fourth/second conductive pattern 225z0, may be implemented as a step-like structure in the extending region ER.

The first/first conductive pattern 205x0 and the first/second conductive pattern 225x0 may be arranged spaced apart from the second/first conductive pattern 205x1 and the second/second conductive pattern 225x1, which are arranged adjacent to each other in the first direction D1, by a first distance d1. The first/first conductive pattern 205x0 and the first/second conductive pattern 225x0 may be arranged spaced apart from the third/first conductive pattern 205y1 and the third/second conductive pattern 225y1, which are arranged adjacent to each other in the opposite direction of the first direction D1, by a second distance d2 that is closer than the first distance d1. For example, the second/first conductive pattern 205x1 and the third/first conductive pattern 205y1 may be each arranged adjacent to the first/first conductive pattern 205x0 at the same height in the first direction D1, and the first distance d1 between the first/first conductive pattern 205x0 and the second/first conductive pattern 205x1 may be greater than the second distance d2 between the first/first conductive pattern 205x0 and the third/first conductive pattern 205y1.

The second/first conductive pattern 205x1 and the second/second conductive pattern 225x1 may be arranged to be spaced from the fourth/first conductive pattern 205z0 and the fourth/second conductive pattern 225z0, which are arranged adjacent to each other in the first direction D1, by the second distance d2 that is closer than the first distance d1. For example, the first/first conductive pattern 205x0 and the fourth/first conductive pattern 205z0 may be each placed adjacent to the second/first conductive pattern 205x1 at the same height in the first direction D1, and the first distance d1 between the second/first conductive pattern 205x1 and the first/first conductive pattern 205x0 may be greater than the second distance d2 between the second/first conductive pattern 205x1 and the fourth/first conductive pattern 205z0.

In the extending region ER, the second insulating pattern 156 may be arranged between the first/first conductive pattern 205x0 and the first/second conductive pattern 225x0, and the second/first conductive pattern 205x1 and the second/second conductive pattern 225x1. In the extending region ER, a separation insulating layer 310 may be arranged between the first/first conductive pattern 205x0 and the first/second conductive pattern 225x0, and the third/first conductive pattern 205y1 and the third/second conductive pattern 225y1, and a separation insulating layer 310 may be arranged between the second/first conductive pattern 205x1 and the second/second conductive pattern 225x1, and the fourth/first conductive pattern 205z0 and the fourth/second conductive pattern 225z0. The separation insulating layer 310 may be placed through a word line cut, as in the manufacturing method described below.

Although not shown, the three-dimensional ferroelectrics device 10a according to the implementation may further include a conductive pattern separated from the third/first conductive pattern 205y1 and the third/second conductive pattern 225y1 by the first distance d1 in the first direction D1, and a conductive pattern separated from the fourth/first conductive pattern 205z0 and the fourth/second conductive pattern 225z0 by the first distance d1 in the first direction D1.

Referring to FIG. 2 to FIG. 6, the three-dimensional ferroelectric memory device 10a may include a bit line 120, first/first and first/second conductive patterns 205x0 and 225x0, second/first and second/second conductive patterns 205x1 and 225x1 disposed on the substrate 100, and gate insulating layers 220 and 240, a channel 250, a capacitor electrode 145, a ferroelectric pattern 155, a separation pattern 165, and a plate line 270a.

Also, the three-dimensional ferroelectric memory device 10a may further include a lower insulating pattern 135, first to fourth insulating patterns 146, 156, 235, and 260, an insulating layer 195, an interlayer insulating layer 190, and a separation insulating layer 310.

The substrate 100 may include an insulating material, a semiconductor material, or a silicon material doped with an impurity. By way of example, the substrate 100 may be a P-type silicon. but is not limited thereto.

The bit line 120 may be extended in the first direction D1 on the substrate 100 and may be formed in multiple pieces spaced apart from each other along the second direction D2. According to the implementation, an interlayer insulating layer 190 may be placed between the bit lines 120. Accordingly, the bit lines 120 and the interlayer insulating layers 190, each extending in the first direction D1 on the substrate 100, may be alternately and repeatedly arranged along the second direction D2.

The first/first and first/second conductive patterns 205x0 and 225x0, and the second/first and second/second conductive patterns 205x1 and 225x1, respectively, may be formed on the bit line 120 and the substrate 100 and may extend in the second direction D2. Additionally, the first/first and first/second conductive patterns 205x0 and 225x0 and the second/first and second/second conductive patterns 205x1 and 225x1 may be formed in multiples so as to be spaced apart from each other along the first direction D1. For example, the first/first conductive pattern 205x0 and the second/first conductive pattern 205x1 may be arranged spaced apart from each other along the first direction D1 at the same height with the substrate 100 as a reference. Additionally, the first/second conductive pattern 225x0 and the second/second conductive pattern 225x1 may be arranged spaced apart from each other along the first direction D1 at the same height with the substrate 100 as a reference.

According to one or more implementations, the first/first conductive pattern 205x0 and the second/first conductive pattern 205x1 may be operated as a block selection line of the three-dimensional ferroelectric memory device 10a, and the first/second conductive pattern 225x0 and the second/second conductive pattern 225x1 may be operated as a word line of the three-dimensional ferroelectric memory device 10a. At this time, the first/second conductive pattern 225x0 may be arranged in plural so as to be spaced apart from each other along the third direction D3 on the first/first conductive pattern 205x0. Similarly, the second/second conductive pattern 225x1 may be arranged in multiples spaced apart from each other along the third direction D3 on the second/first conductive pattern 205x1.

The first insulating pattern 146 may be arranged between the first/first conductive pattern 205x0 and the lowermost first/second conductive pattern 225x0, between the second/first conductive pattern 205x1 and the lowermost second/second conductive pattern 225x1, between the first/second conductive patterns 225x0, between the second/second conductive patterns 225x1, between the uppermost first/second conductive pattern 225x0 and the third insulating pattern 235, and between the uppermost second/second conductive pattern 225x1 and the third insulating pattern 235.

The third insulating pattern 235 may be arranged on the uppermost first insulating pattern 146, the uppermost capacitor electrode 145, and the interlayer insulating layer 190, and may extend in the second direction D2.

The insulating layer 195 may be arranged on the bit line 120 and the substrate 100 and be extended in the second direction D2, and may be spaced apart from each other along the first direction D1 or separated from each other by the separation insulating layer 310 to be formed in plural. Each insulating layer 195 may be disposed along the upper surface of the bit line 120 and the substrate 100, the lower and upper surface of the first/first conductive pattern 205x0 and the second/first conductive pattern 205x1 and the side wall into the first direction D1, the upper and lower surface of the first/second conductive pattern 225x0 and the second/second conductive pattern 225x1 and the side walls in the first direction D1, and the lower surface of the third insulating pattern 235 and the side wall in the first direction D1.

The insulating layer 195 may be interposed between the bit line 120 and the first/first conductive pattern 205x0, between the bit line 120 and the second/first conductive pattern 205x1, between the first/first conductive pattern 205x0 and the capacitor electrode 145, between the first/second conductive pattern 225x0 and the capacitor electrode 145, between the first/second conductive pattern 225x0 and the capacitor electrode 145, between the second/second conductive pattern 225x1 and the capacitor electrode 145, between the first/second conductive pattern 225x0 and the ferroelectric pattern 155, and between the second/second conductive pattern 225x1 and the ferroelectric pattern 155. Through the insulating layer 195, conductive materials within the three-dimensional ferroelectrics device 10a can be electrically separated.

The channel 250 may have a pillar shape formed on the upper surface of the bit line 120 through the first/first and first/second conductive patterns 205x0 and 225x0, the second/first and second/second conductive patterns 205x1 and 225x1, the first and third insulating patterns 146 and 235, and the insulating layer 195 and extending in the third direction D3. Accordingly, the first/first and first/second conductive patterns 205x0 and 225x0, and the second/first and second/second conductive patterns 205x1 and 225x1, respectively, may surround channel 250. According to one or more implementations, the channel 250 may have various shapes as a flat area. For example, the channel 250 may have a shape such as a circle, an ellipse, a polygon, or a polygon with rounded corners as a flat area.

In visual implementations, the channel 250 may be arranged in multiples spaced apart from each other along the first direction D1 on one bit line 120, and may also be spaced apart from each other along the second direction D2 on the different bit lines 120. Accordingly, they may be arranged in multiple spaced apart from each other along the first and second directions D1 and D2.

The channel 250, for example, may include Si, Ge, SiGe, Group III-V semiconductor, oxide semiconductor, nitride semiconductor, oxynitride semiconductor, two-dimensional material (2D material), quantum dot, or organic semiconductor. The oxide semiconductor may include InGaZnO, IGZO, two-dimensional material may include MoS2, TMD (transition metal dichalcogenide) or graphene, and quantum dot may include colloidal QD, nanocrystal.

Although not shown, some regions of the channel 250 may be doped with dopants according to implementations. Additionally, although not shown, a drain electrode may be placed at one end of the channel 250 and connected to the bit line 120, and a source electrode may be placed at the other end of the channel 250 and connected to the plate line 270a.

According to one or more implementations, gate insulating layers 220 and 240 may be interposed between the first/first and first/second conductive patterns 205x0 and 225x0 and the channel 250, and between the second/first and second/second conductive patterns 205x1 and 225x1 and the channel 250. Accordingly, the gate insulating layers 220 and 240 may have a ring shape surrounding the side wall of the channel 250. The gate insulating layers 220 and 240 may include various insulator materials, such as SiO, SiN, AlO, HfO, ZrO, and may be formed of a combination of two or more. The thickness of the gate insulating layers 220 and 240 may range from approximately 1 to 10 nm, but is not limited thereto.

Also, the gate insulating layer 220, and 240 may be interposed between the first/first and first/second conductive patterns 205x0 and 225x0 and the insulating layer 195 and between the second/first and second/second conductive patterns 205x1 and 225x1 and the insulating layer 195. Although not shown, a high dielectric constant dielectric material such as a barrier metal to control an energy band may be arranged between the first/first and first/second conductive patterns 205x0 and 225x0 and the gate insulating layers 220 and 240 and between the second/first and second/second conductive patterns 205x1 and 225x1 and the gate insulating layers 220 and 240.

The high dielectric constant dielectric material, for example, may include aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide HfO2, hafnium silicon oxide (HfSixOy), lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3), etc.

A lower insulating pattern 135 may be placed on each bit line 120, and on the second lower insulating pattern 135, a capacitor electrodes 145 and a ferroelectric patterns 155 may be alternately and repeatedly stacked along the third direction D3. The capacitor electrode 145 and the ferroelectric pattern 155 may be placed between the channels 250 arranged on one bit line 120. Between the channels 250 arranged on one bit line 120, two capacitor electrodes 145 arranged at the same height may be separated and arranged by the separation pattern 165. Between the channel 250 arranged on one bit line 120, two capacitor electrodes 145 arranged at the same height may be arranged non-overlapping with each other in a flat area. In some implementations, the capacitor electrode 145 can be shared by adjacent ferroelectric patterns 155 arranged along the third direction. For example, the capacitor electrode 145 can be in contact with both ferroelectric patterns 155 positioned on opposite sides of the capacitor electrode 145 along the third direction.

On the lower insulating pattern 135, a capacitor structure including the capacitor electrode 145-ferroelectrics material pattern 155-capacitor electrode 145 stacked in the third direction D3 may be operated as two ferroelectrics capacitors arranged at the same height by the separation pattern 165. The lower insulating pattern 135 and the capacitor structure may form a stacking structure together. The stacking structure may be extended in the first direction D1 by a certain length between the channels 250 arranged on one bit line 120. According to the arrangement of the bit line 120, the stacking structure may be formed in plural pieces spaced apart from each other along the second direction D2.

In the drawing, the width of the stacking structure in the second direction D2 is shown to be smaller than the width of the corresponding bit line 120 in the second direction D2, but the technical idea of the present disclosure is not limited thereto and it may be substantially the same or greater.

The lower insulating pattern 135 may be in contact with the upper surface of the bit line 120, the side wall of the insulating layer 195 in the first direction D1, and the lower surface of the lowermost capacitor electrode 145. The ferroelectrics material pattern 155 may be placed between and in contact the adjacent capacitor electrodes 145 in the third direction D3.

In some implementations, the length of the ferroelectric pattern 155 in the first direction D1 may be substantially the same as the length of the lower insulating pattern 135 in the first direction D1, and the side wall of the ferroelectric pattern 155 in the first direction D1 may be aligned with the side wall of the corresponding lower insulating pattern 135 in the first direction D1 in the third direction D3.

The ferroelectrics material pattern 155 includes ferroelectrics materials, and the ferroelectrics materials have a ferroelectricity in which internal electric dipole moments are aligned and spontaneous electric polarization is maintained even when no electric field is applied from the outside. When a certain voltage is applied to the ferroelectric material and the voltage is returned to 0 V, a residual polarization (or an electric field) remains semi-permanently within the ferroelectric material. This may be used to implement a non-volatile memory performance.

The ferroelectrics material pattern 155 may include all materials based on HfO with a fluorite structure, nitride-based ferroelectrics such as AIScN, and perovskite structure ferroelectrics such as PZT, SBT, and BTO. Additionally, the ferroelectrics may include orthorhombic crystal phases. For example, the ferroelectric material included in the ferroelectric pattern 155 may include multiple crystal phases, such as orthorhombic crystal phase and tetragonal crystal phase, and may dominantly include the orthorhombic crystal phase with the largest ratio of all crystal phases.

The ferroelectric materials may be distinguished from high-dielectric material depending on the presence/size of the remaining polarization, the composition of metal oxide, the type and ratio of doping elements, and the crystal phase. The type and content of each element may be measured according to a method known in the art, for example, XPS (X-ray photoelectron spectroscopy), AES (Auger electron spectroscopy), ICP (Inductively coupled plasma), etc. may be used. Additionally, the distribution of the crystal phase may be confirmed by methods known in the art, for example, TEM (Transmission electron microscopy) and GIXRD (Grazing Incidence X-ray Diffraction) may be used.

According to one or more implementations, each capacitor electrode 145 may extend from the separation pattern 165 in the first direction D1 or in the opposite direction to the first direction D1, and one end of each capacitor electrode 145 may be protruded in a direction extending from both side walls of the ferroelectric pattern 155 and the lower insulating pattern 135 in the first direction D1.

According to one or more implementations, at least a portion of the capacitor electrode 145 may overlap the first/first and first/second conductive patterns 205x0 and 225x0 and the second/first and second/second conductive patterns 205x1 and 225x1 in a flat area. According to one or more implementations, the capacitor electrode 145 may be electrically connected by being in contact with the side wall of the channel 250.

Referring to FIG. 6, the second thickness T2 of each ferroelectric pattern 155 in the third direction D3 may be greater than the first thickness T1 of the corresponding first/second conductive pattern 225x0 and second/second conductive pattern 225x1 in the third direction D3. Accordingly, the upper surface of the first/second conductive pattern 225x0 may be lower than the upper surface of the corresponding ferroelectric pattern 155, and the lower surface of the first/second conductive pattern 225x0 may be higher than the lower surface of the corresponding ferroelectric pattern 155. According to one or more implementations, the first thickness T1 may range from 20 to 100 nm, but is not limited thereto.

According to one or more implementations, the separation pattern 165 and the capacitor electrode 145, which is separated in the first direction D1 by the separation pattern 165, may be in contact with the upper surface of the ferroelectric pattern 155, which is arranged at the bottom, and the separation pattern 165 and the capacitor electrode 145, which is separated in the first direction D1 by the separation pattern 165, may be in contact with the bottom surface of the ferroelectric pattern 155 arranged on the upper side. The uppermost separation pattern 165 and the uppermost capacitor electrode 145 may be in contact with the upper surface of the uppermost ferroelectric pattern 155 and may be arranged below the interlayer insulating layer 190 and the third insulating pattern 235. The lowermost separation pattern 165 and the lowermost capacitor electrode 145 may be in contact with the bottom surface of the lowermost ferroelectric pattern 155 and in contact with the upper surface of the lower insulating pattern 135.

The side wall of the capacitor electrode 145, the separation pattern 165, and the ferroelectric pattern 155 in the second direction D2 may be in contact with the interlayer insulating layer 190. The interlayer insulating layer 190 may be interposed between the stacking structures adjacent to each other in the second direction D2 and between the third insulating pattern 235 separated from each other in the first direction D1, thereby covering the stacking structure.

The plate line 270a may be arranged on the upper surfaces of the interlayer insulating layer 190, the insulating layer 195, the third insulating pattern 235, the separation insulating layer 310, and the channel 250 and in contact with them. According to one or more implementations, the plate line 270a may extend in the second direction D2 to be in contact with the upper surface of the channel 250 arranged in the second direction D2, and be in contact the upper surfaces of two channels 250 connected to one bit line 120 and spaced apart in the first direction D1.

The plate lines 270a may be arranged in multiple places spaced apart from each other along the first direction D1 by the fourth insulating pattern 260. The fourth insulating pattern 260 may be arranged on the separation insulating layer 310 so as to separate the plate lines 270a adjacent to each other in the first direction D1.

Each of the bit line 120, the first/first and first/second conductive patterns 205x0 and 225x0, the second/first and second/second conductive patterns 205x1 and 225x1, the capacitor electrode 145, and the plate line 270a, for example, may include a conductive material such as a metal, a metal nitride, a metal silicide. Additionally, each of the lower insulating pattern 135, the first to fourth insulating patterns 146, 156, 235, and 260, the insulating layer 195, the interlayer insulating layer 190, and the separation insulating layer 310 may include, for example, an oxide such as silicon oxide, an insulating nitride such as silicon nitride, or an insulating polysilicon. At this time, some of the first to fourth insulating patterns 146, 156, 235, and 260 and the interlayer insulating layer 190 may include substantially the same material and be merged.

In the three-dimensional ferroelectric memory device 10a according to the implementation, the ferroelectric pattern 155 interposed between the pair of capacitor electrodes 145 and the pair of capacitor electrodes 145 adjacent in the third direction D3 may form one ferroelectrics capacitor, and the ferroelectric capacitors may be stacked in multiples along the third direction D3 and coupled in series. The ferroelectric capacitors adjacent to each other in the third direction D3 may share the capacitor electrode 145. Accordingly, the integration of the three-dimensional ferroelectric memory device may be improved.

In the three-dimensional ferroelectric memory device 10a according to the implementation, the ferroelectric capacitors arranged at the same height and separated in the first direction D1 by the separation pattern 165 may share the ferroelectric pattern 155. Accordingly, the integration of the three-dimensional ferroelectric memory device 10a may be improved.

The bit line 120 may extend in the first direction D1 on the substrate 100, and the bit line 120 may include a zeroth bit line BL0, a first bit line BL1, a second bit line BL2, a third bit line BL3, etc., which are arranged to be spaced apart from each other along the second direction D2. Additionally, the first/first and second/first conductive patterns 205x0 and 205x1 may be extended in the second direction D2 on the bit line 120, and each of the first/first and second/first conductive patterns 205x0 and 205x1 spaced apart from each other along the first direction D1 may correspond to the 0th block selection line BS0 and the first block selection line BS1.

Each of the first/second and second/second conductive patterns 225x0 and 225x1 may be extended in the second direction D2 on the first/first and second/first conductive patterns 205x0 and 205x1 corresponding to the zeroth and first block selection lines BS0 and BS1, respectively, and may be arranged in multiple pieces so as to be spaced apart from each other along the third direction D3. For example, the first/second conductive pattern 225x0 arranged on the first/first conductive pattern 205x0 corresponding to the 0-th block selection line BS0 may include a (0_0)-th word line WL00, a (zeroth/first)-th word line WL01, a (0_2)-nd word line WL02, a (0_3)-rd word line WL03, etc., which are stacked in the third direction D3. Additionally, the second/second conductive pattern 225x1 arranged on the second/first conductive pattern 205x1 corresponding to the first block selection line BS1 may include a first/zero word line WL10, a first/first word line WL11, a first/second word line WL12, a first/third word line WL13, etc., which are stacked in the third direction D3.

The plate line 270a may include a zeroth plate line PL0, etc., which extends in the second direction D2 on the first/second and second/second conductive patterns 225x0 and 225x1 and is arranged along the first direction D1.

Meanwhile, the channel 250 may be extended in the third direction D3, i.e., the vertical direction to penetrate the first/second and second/second conductive patterns 225x0 and 225x1 and the first/first and second/first conductive patterns 205x0 and 205x1 stacked along the third direction D3 and be in contact with the upper surface of the bit line 120 and the lower surface of the plate line 270a to be electrically connected to the bit line 120 and the plate line 270a. According, each of the first/second and second/second conductive patterns 225x0 and 225x1 or the first/first and second/first conductive patterns 205x0 and 205x1, the channel 250 part corresponding in the horizontal direction, and the gate insulating layers 220 and 240 interposed therebetween may operate as a transistor, and the transistor and the ferroelectrics capacitor formed at the same height may operate as one memory cell.

The memory cells included in the three-dimensional ferroelectric memory device 10a may be arranged not only along the horizontal direction, i.e., along the first and second directions D1 and D2, on the substrate 100, but also along the third direction D3. At this time, the memory cells arranged in the third direction D3 may form a memory cell chain, which is a memory cell string, and the memory cell strings arranged along the second direction D2 may form a memory block together.

Through the shared structure for the ferroelectric pattern 155 between the memory cell strings adjacent in the first direction D1, the three-dimensional ferroelectric memory device 10a according to the implementation may separate the first/second and second/second conductive patterns 225x0 and 225x1 and the ferroelectric pattern 155 and the capacitor electrode 145 of the adjacent memory cell strings far apart, and suppress the effect of a parasitic capacitor occurring between the first/second and second/second conductive patterns 225x0 and 225x1, and the ferroelectric pattern 155 and the capacitor electrode 145.

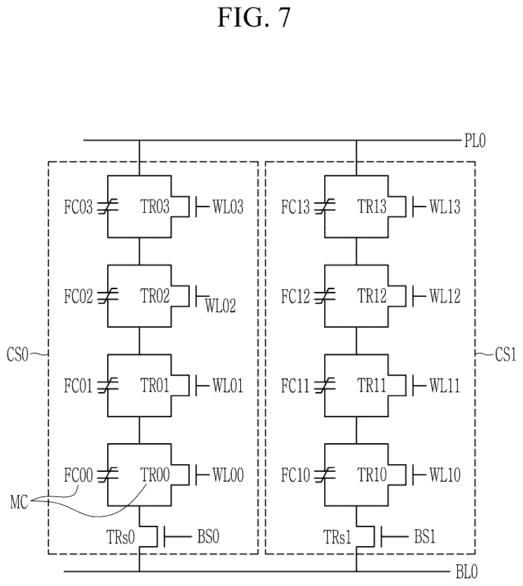

FIG. 7 is a circuit diagram showing a memory cell string included in a three-dimensional ferroelectric memory device according to one or more implementations. Specifically, FIG. 7 may be a circuit diagram corresponding to the structures in the cross-section of FIG. 4.

Referring to FIG. 2 to FIG. 4, and FIG. 7, a three-dimensional ferroelectric memory device 10a may include a zeroth memory cell string CS0 and a first memory cell string CS1 connected between a zeroth plate line PL0 and a zeroth bit line BL0. The zeroth memory cell string CS0 and the first memory cell string CS1 may be connected in parallel between the zeroth plate line PL0 and the zeroth bit line BL0.

The zeroth memory cell string CS0 may include a zeroth block selection transistor TRs0 and zeroth/zeroth to zeroth/third transistors TR00 to TR03 of which gate terminals are respectively connected to a zeroth block selection line BS0 and zeroth/zeroth to zeroth/third word lines WL00 to WL03 stacked in the third direction D3. Additionally, the zeroth memory cell string CS0 may include zeroth/zeroth to zeroth/third ferroelectrics capacitors FC00 to FC03 coupled in parallel to the zeroth/zeroth to the zeroth/third transistors TR00 to TR03, respectively. According to the implementation, the zeroth/zeroth to the zeroth/third ferroelectrics capacitors FC00 to FC03 may be respectively arranged at the same height as the zeroth/zeroth to the zeroth/third word lines WL00 to WL03, and the zeroth/zeroth to the zeroth/third ferroelectrics capacitors FC00 to FC03 may be coupled in series along the third direction D3.

The first memory cell string CS1 may include first block selection transistor TRs1 and first/zeroth to first/third transistors TR10 to TR13 of which gate terminals are connected to the first block selection line BS1 and the first/zeroth to first/third word lines WL10 to WL13 stacked in the third direction D3, respectively. Additionally, the first memory cell string CS1 may include first/zeroth to first/third ferroelectric capacitors FC10 to FC13 coupled in parallel to the first/zeroth to first/third transistors TR10 to TR13, respectively. According to the implementation, the first/zeroth to first/third ferroelectric capacitors FC10 to FC13 may be respectively arranged at the same height as the first/zeroth to first/third word lines WL10 to WL13, and the first/zeroth to first/third ferroelectric capacitors FC10 to FC13 may be coupled in series along the third direction D3.

The transistors and the ferroelectric capacitors coupled in parallel form a memory cell MC, and the memory cells MC may be coupled in series with each other within the memory cell strings CS0 and CS1 to form a chain. For example, the zeroth/zeroth transistor TR00 and the zeroth/zeroth ferroelectrics capacitor FC00 may form the memory cell MC.

Each of the zeroth/zeroth to the zeroth/third ferroelectrics capacitors FC00 to FC03 and each of the first/zeroth to first/third ferroelectrics capacitors FC10 to FC13 may be arranged at the same height in the third direction D3. Each of the zeroth/zeroth to the zeroth/third ferroelectrics capacitors FC00 to FC03 and each of the first/zeroth to first/third ferroelectrics capacitors FC10 to FC13, which are arranged at the same height, may share the ferroelectric pattern 155.

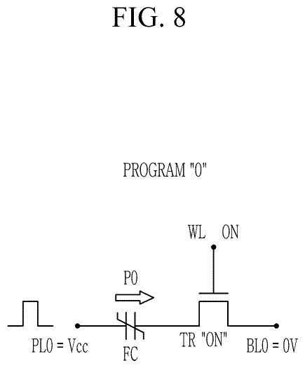

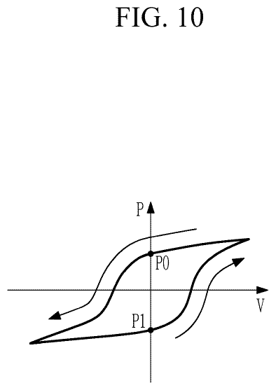

FIG. 8 to FIG. 10 are views for explaining a program operation of a memory cell included in a three-dimensional ferroelectric memory device according to one or more implementations. Specifically, FIG. 10 is a hysteresis curve for a memory cell.

Referring to FIG. 8 and FIG. 10, the transistor of the memory cell that is a target of an operation is turned off, the transistor TR connected to the memory cell that is not the target of the operation is turned on (ON), and when 0V is applied to the zeroth bit line BL0 and Vcc voltage is applied to the zeroth plate line PL0, an electric field in the first direction may be formed in the ferroelectric capacitor FC of the memory cell that is the target of the operation and by the electric field, the ferroelectric capacitor FC becomes the first polarization state P0 and “0” may be programmed.

Afterwards, even if the zeroth bit line BLO and the zeroth plate line PL0 remain at 0 V, the polarization state of the ferroelectric capacitor FC may do not change and the first polarization state P0 may be maintained as it is. Also, the polarization switching does not occur when the electric field is not formed in the opposite direction to the first direction according to the material characteristic of the ferroelectric pattern 155 in the ferroelectric capacitor FC.

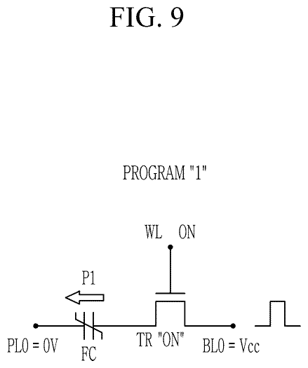

Referring to FIG. 9 and FIG. 10, in the state that the transistor of the memory cell that is the target of the operation is turned off, the transistor TR connected to the memory cell that is not the target of the operation is turned on (ON), and 0 V is applied to the plate line PL, if the voltage Vcc is applied, an electric field in the opposite direction to the first direction may be formed in the ferroelectric capacitor FC of the memory cell that is the target of the operation, by the electric field, the ferroelectric capacitor FC may be programmed to be “1” by changing from the first polarization state PO to the second polarization state P1 in the opposite direction.

Afterwards, even if the zeroth bit line BL0 and the zeroth plate line PL0 remain at 0 V, the polarization state of the ferroelectric capacitor FC does not change and the second polarization state P1 may be maintained as is. Also, the polarization switching does not occur when the electric field is not formed in the first direction according to the material characteristic of the ferroelectric pattern 155 in the ferroelectric capacitor FC.

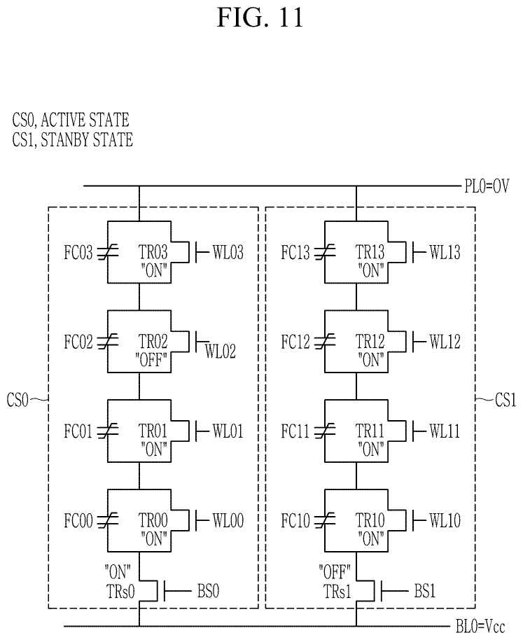

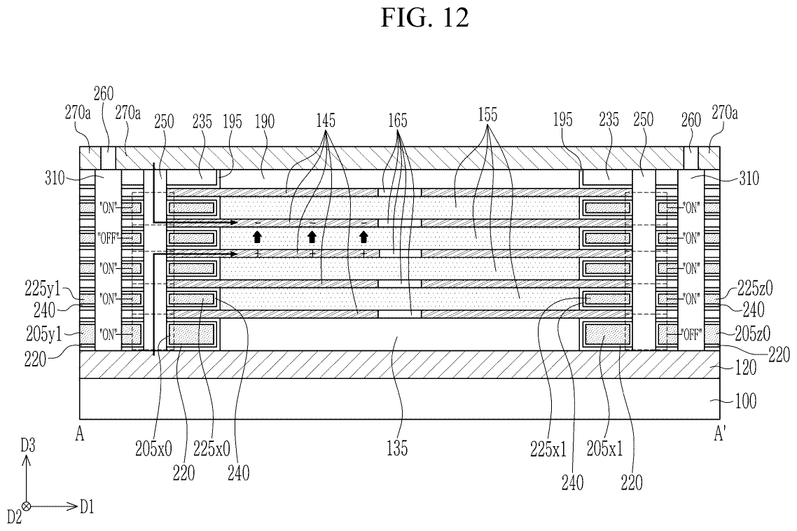

FIG. 11 and FIG. 12 are view for explaining an operation of a memory cell string included in a three-dimensional ferroelectric memory device according to one or more implementations. Specifically, FIG. 11 and FIG. 12 are drawings for explaining the operation of the memory cell strings corresponding to the cross-section of FIG. 4.

Referring to FIG. 2 to FIG. 4, FIG. 11, and FIG. 12, the zeroth memory cell string CS0 and the first memory cell string CS1, which are connected in parallel between the zeroth plate line PL0 and the zeroth bit line BL0, may operate complementarily with each other when performing the memory operation. The memory operations may include read operations, program operations, etc.

When an electric signal is applied to the zeroth bit line BL0, the zeroth block selection transistor TRs0 and the first block selection transistor TRs1 may be selectively turned on. As an example, referring to FIG. 11, when the memory cell connected to the zeroth/second word line WL02 is the target of the operation, the zeroth block selection transistor TRs0 is turned on so that the zeroth memory cell string CS0 may be activated, and the first block selection transistor TRs1 is turned off so that the first memory cell string CS1 may be in a standby state. In the operation of the first memory cell string CS1 in the standby state, the first/zeroth to first/third transistors TR10 to TR13 are turned on so that the data stored in the first/zeroth to first/third ferroelectric capacitors FC10 to FC13 may be preserved.

For example, when accessing and operating the memory cell connected to the zeroth/second word line WL02, the zeroth block selection transistor TRs0, the zeroth/zeroth to the zeroth/first transistors TR00 and TR01, the zeroth/third transistor TR03, and the first/zeroth to the first/third transistors TR10 to TR13 may be turned on and the first block selection transistor TRs1 and the zeroth/second transistor TR02 may be turned off, only the zeroth/second ferroelectrics capacitor FC02 may be activated by applying a bias voltage. Therefore, the zeroth block selection transistor TRs0 and the first block selection transistor TRs1 can be configured to operate in opposite states, e.g., one is turned on, and the other one is turned off.

For example, when accessing the memory cell connected to the zeroth/second word line WL02 and writing “1”, when the voltage Vcc is applied to the zeroth bit line BL0 and 0V is applied to the zeroth plate line PL0, “1” may be programmed to the zeroth/second ferroelectrics capacitor FC02. Conversely, when accessing the memory cell connected to the zeroth bit line BL0 and the zeroth plate line PL0 and writing “0”, 0V may be applied to the zeroth bit line BL0 and Vcc may be applied to the zeroth plate line PL0, and “0” may be programmed to the ferroelectric capacitor of the memory cell.

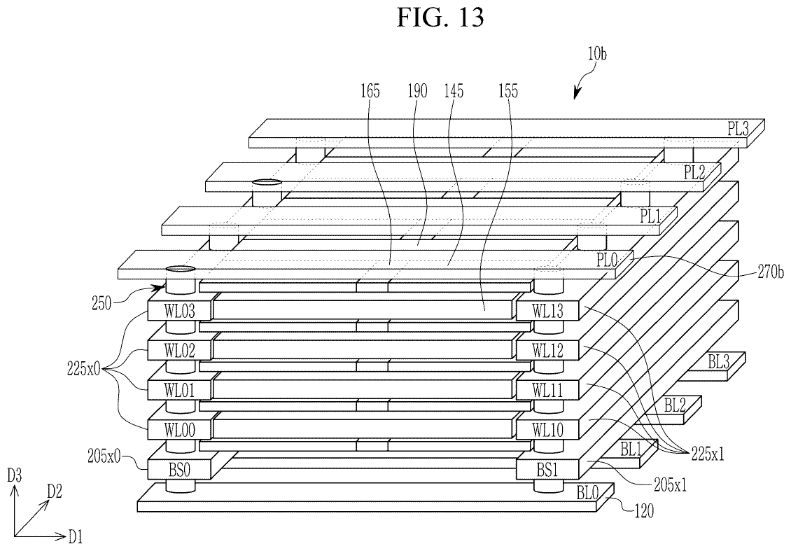

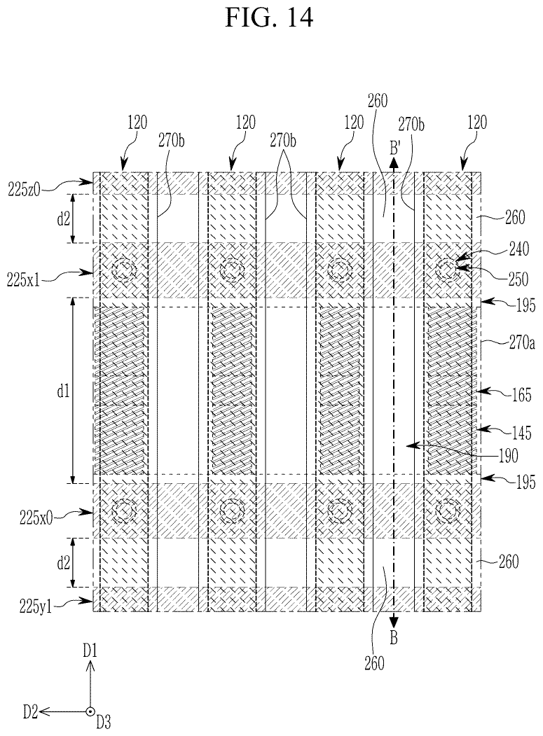

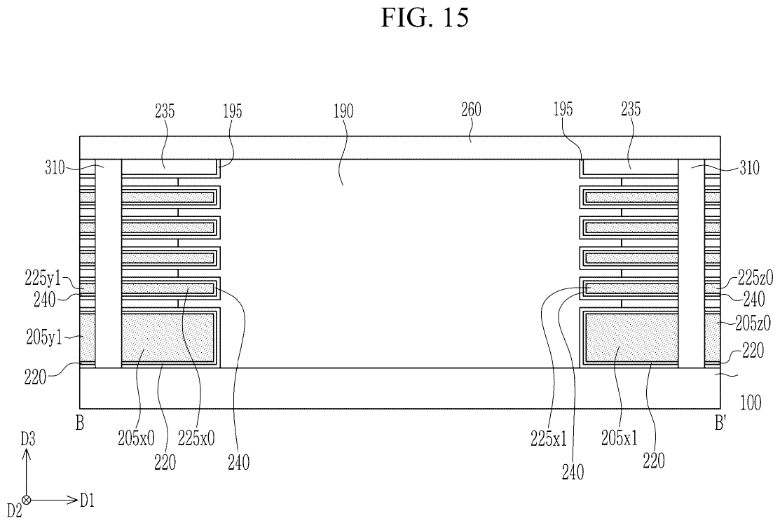

FIG. 13 is a perspective view showing a cell region of a three-dimensional ferroelectric memory device according to one or more implementations. FIG. 14 is a top plan view showing a cell region of a three-dimensional ferroelectric memory device according to one or more implementations. FIG. 15 is a cross-sectional view taken along a line B-B′ of FIG. 14. Specifically, FIG. 14 is the top plan view showing the portion of the region within the three-dimensional ferroelectric memory device 10b of FIG. 13.

The three-dimensional ferroelectric memory device 10b of FIG. 13 to FIG. 15 may correspond to the three-dimensional ferroelectric memory device 10a of FIG. 1 to FIG. 6. For ease of explanation, the duplicate explanations are omitted below, and the three-dimensional ferroelectric memory device 10b is described focusing on the differences from the three-dimensional ferroelectric memory device 10a of FIG. 1 to FIG. 6.

The plate line 270b included in the three-dimensional ferroelectric memory device 10b may be placed on and in contact with the upper surfaces of the interlayer insulating layer 190, the insulating layer 195, the third insulating pattern 235, the separation insulating layer 310, and the channel 250. According to one or more implementations, plate line 270b may be in contact with the upper surface of channel 250 extended in the first direction D1 and arranged in the second direction D2, and may be in contact with the upper surface of the plurality of channels 250 connected to one bit line 120 and spaced apart in the first direction D1.

That is, the plate line 270b may be extended along the first direction D1 like the bit line 120. According to the implementation, each plate line 270b may overlap the corresponding bit line 120 in a flat area along the third direction D3.

The plate lines 270b may be arranged in plural spaced apart from each other along the second direction D2 by the fourth insulating pattern 260. The fourth insulating pattern 260 may be arranged on the interlayer insulating layer 190, the third insulating pattern 235, and the separation insulating layer 310, so that the plate lines 270b adjacent to each other in the second direction D2 may be separated from each other.

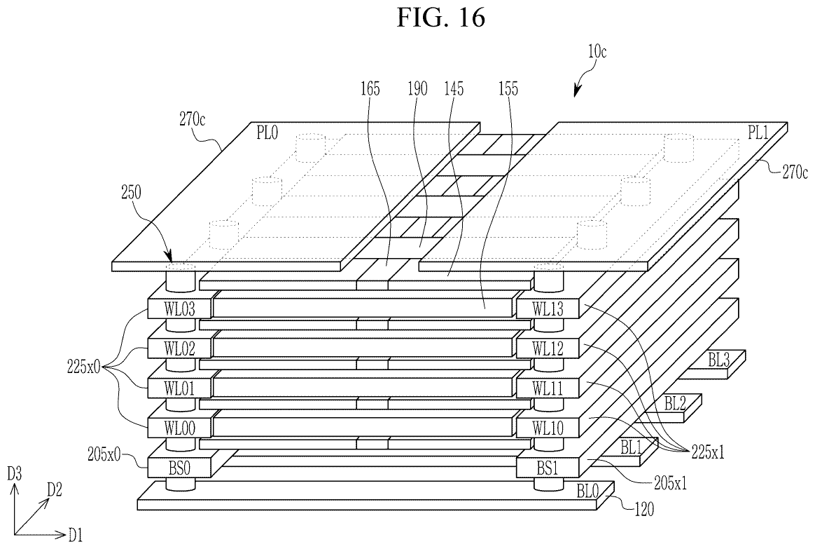

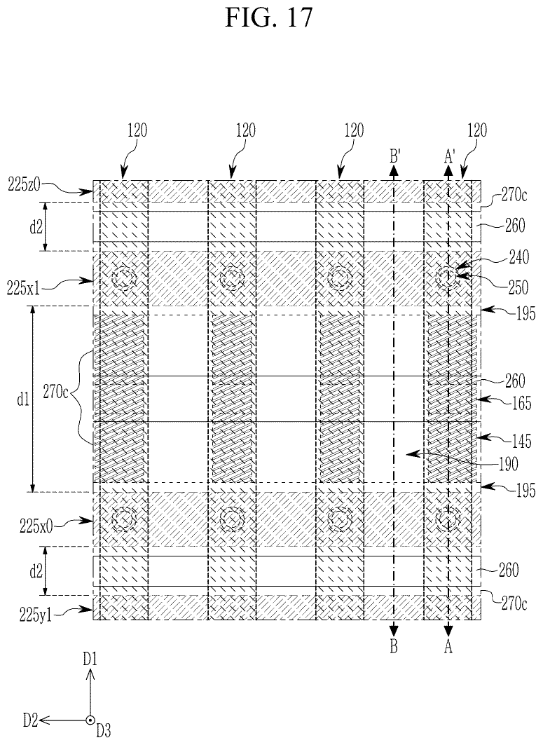

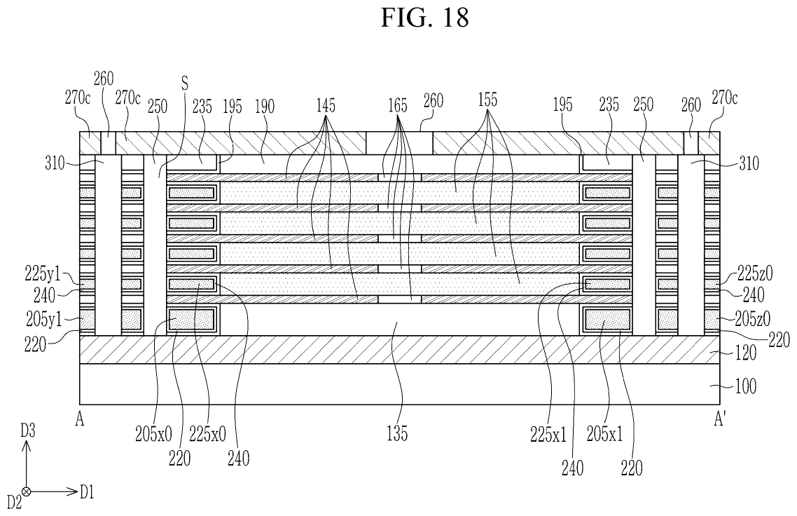

FIG. 16 is a perspective view showing a cell region of a three-dimensional ferroelectric memory device according to one or more implementations. FIG. 17 is a top plan view showing a cell region of a three-dimensional ferroelectric memory device according to one or more implementations. FIG. 18 is a cross-sectional view taken along a line A-A′ of FIG. 17. Specifically, FIG. 17 is the top plan view showing a portion region within the three-dimensional ferroelectric memory device 10c of FIG. 16.

The three-dimensional ferroelectric memory device 10c of FIG. 16 to FIG. 18 may corresponding to the three-dimensional ferroelectric memory device 10a of FIG. 1 to FIG. 6. For ease of explanation, redundant descriptions are omitted below and the three-dimensional ferroelectric memory device 10c is described focusing on the differences from the three-dimensional ferroelectric memory device 10a of FIG. 1 to FIG. 6.

The plate line 270c included in the three-dimensional ferroelectric memory device 10c may be extended in the second direction D2 and may be in contact with the upper surface of the plurality of channels 250 arranged in the second direction D2, and may also be arranged in plural spaced apart from each other along the first direction D1.

The plate line 270c may be disposed on the stacking structure including the lower insulating pattern 135, the capacitor electrode 145, and the ferroelectric pattern 155, which are stacked in the third direction D3, and may be in contact with the upper surfaces of the interlayer insulating layer 190, the insulating layer 195, the third insulating pattern 235, and the channel 250.

The plate lines 270c, which are adjacent to each other in the first direction D1, may be separated by the fourth insulating pattern 260 that extends in the second direction on the interlayer insulating layer 190 or the separation insulating layer 310. The plate line 270c may include the zeroth plate line PL0 and the first plate line PL1, which are spaced apart from each other in the first direction D1 on the first/second and second/second conductive patterns 225x0 and 225x1.

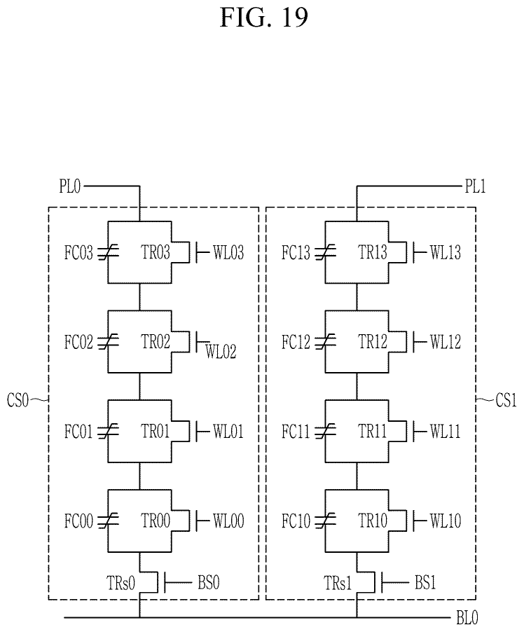

FIG. 19 is a circuit diagram showing a memory cell string included in a three-dimensional ferroelectric memory device according to one or more implementations. Specifically, FIG. 19 may be the circuit diagram corresponding to the structures in the cross-section view of FIG. 18.

Additionally, the circuit diagram of FIG. 19 may correspond to the circuit diagram of FIG. 7. For ease of explanation below, duplicate explanations are omitted and the circuit diagram of FIG. 19 is explained focusing on the differences from the circuit diagram of FIG. 7.

Referring to FIG. 16 to FIG. 18, the three-dimensional ferroelectric memory device 10c may include a zeroth memory cell string CS0 connected between a zeroth plate line PL0 and a zeroth bit line BL0 and a first memory cell string CS1 connected between a first plate line PL1 and a zeroth bit line BL0.

The zeroth memory cell string CS0 may include a zeroth block selection transistor TRs0 and a zeroth/zeroth to a zeroth/third transistors TR00 to TR03 coupled in series between the zeroth bit line BL0 and the zeroth plate line PL0. . . . Additionally, the zeroth memory cell string CS0 may include a zeroth/zeroth to a zeroth/third ferroelectrics capacitors FC00 to FC03 coupled in parallel to the zeroth/zeroth to the zeroth/third transistors TR00 to TR03, respectively.

The first memory cell string CS1 may include a first block selection transistor TRs1 and first/zero to first/third transistors TR10 to TR13 coupled in series between the zeroth bit line BL0 and the first plate line PL1. Additionally, the first memory cell string CS1 may include first/zeroth to first/third ferroelectric capacitors FC10 to FC13 coupled in parallel to the first/zeroth to the first/third transistors TR10 to TR13, respectively.

The transistors and the ferroelectric capacitors coupled in parallel form the memory cell MC, and the memory cell MC may be coupled in series with each other within the memory cell strings CS0 and CS1 to form a chain.

Each of the zeroth/zeroth to the zeroth/third ferroelectrics capacitors FC00 to FC03 and each of the first/zeroth to first/third ferroelectrics capacitors FC10 to FC13 may be arranged at the same height in the third direction D3, and each of the zeroth/zeroth to the zeroth/third ferroelectrics capacitors FC00 to FC03 and each of the first/zeroth to first/third ferroelectrics capacitors FC10 to FC13, which are arranged at the same height, may share a ferroelectric pattern 155.

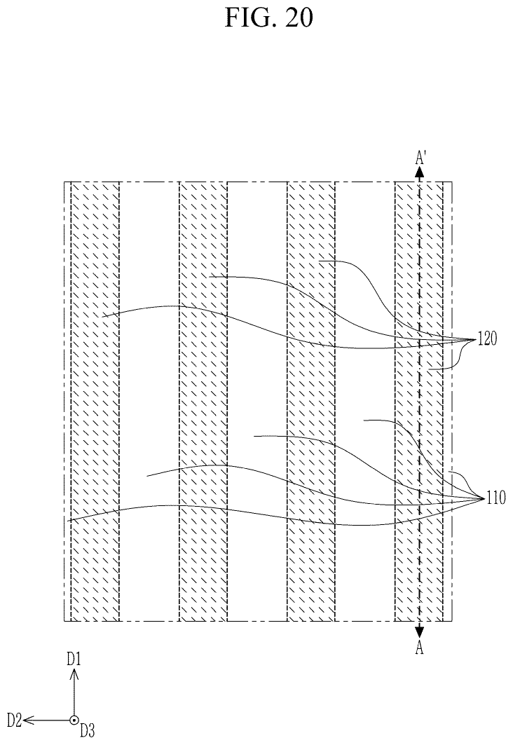

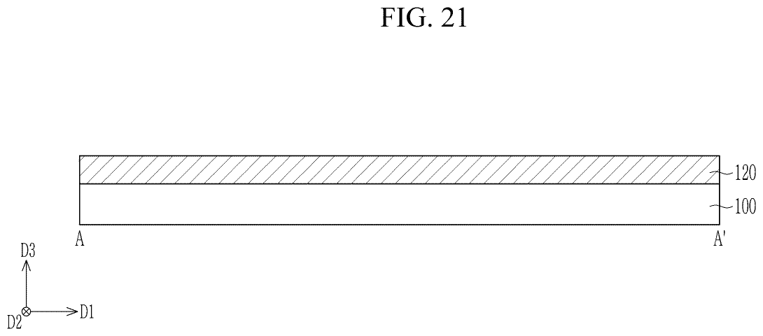

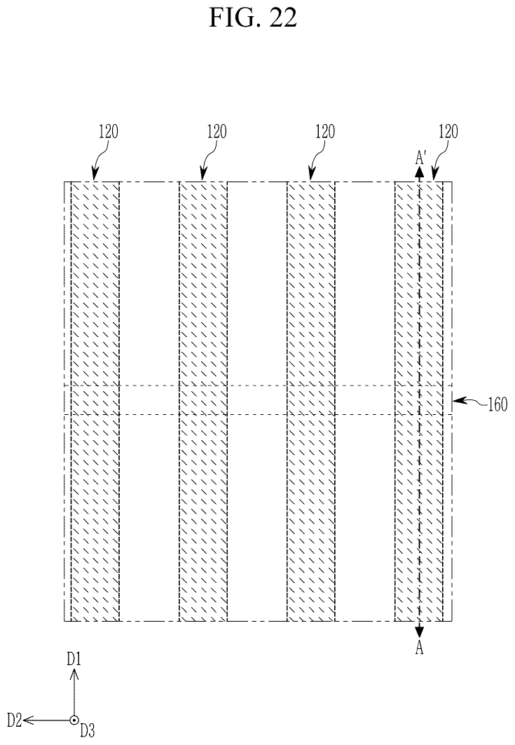

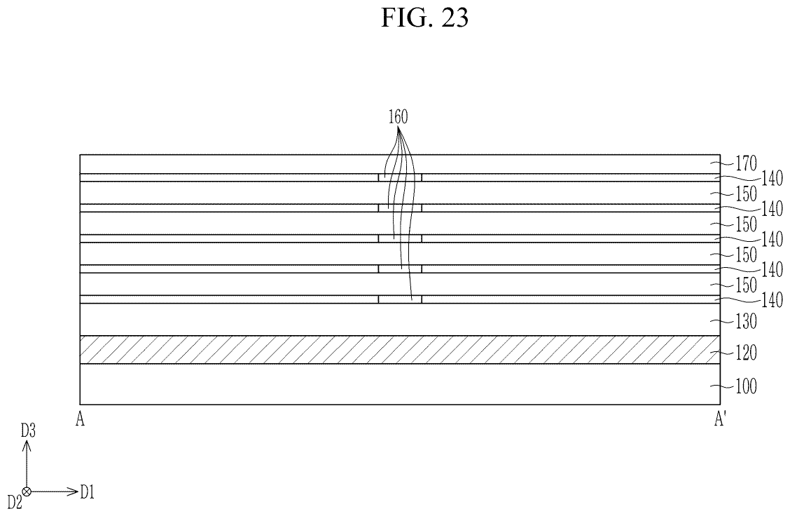

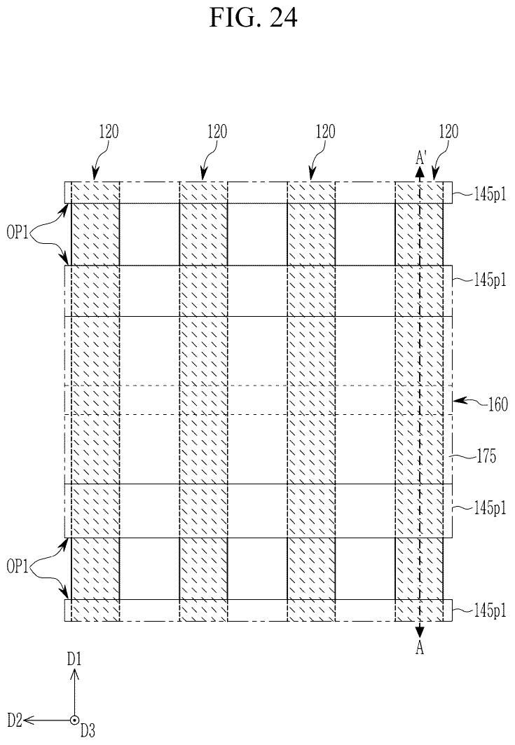

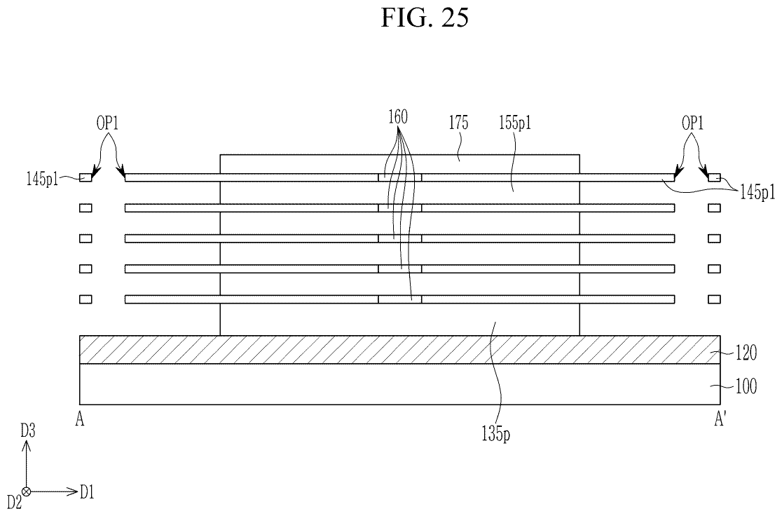

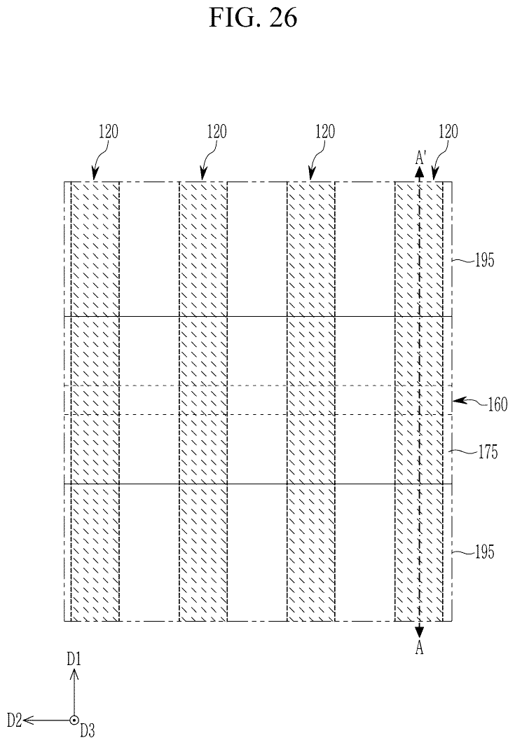

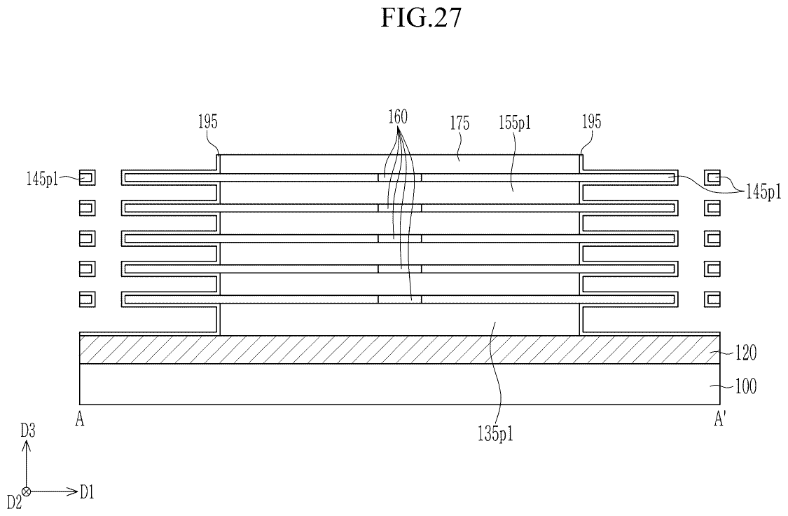

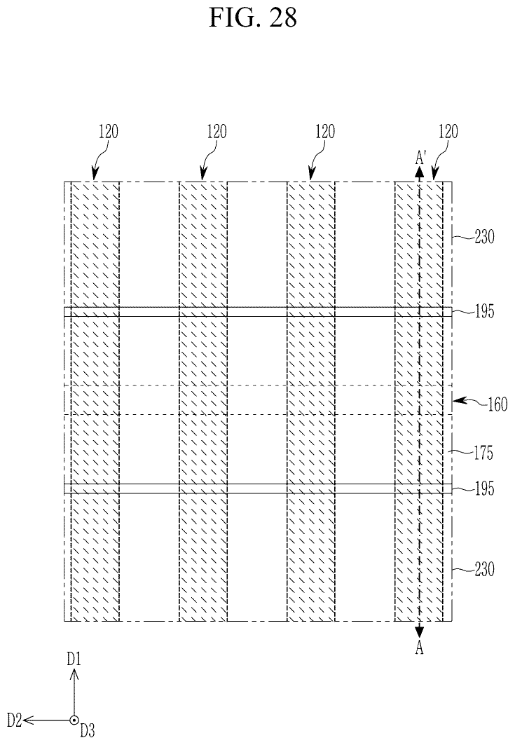

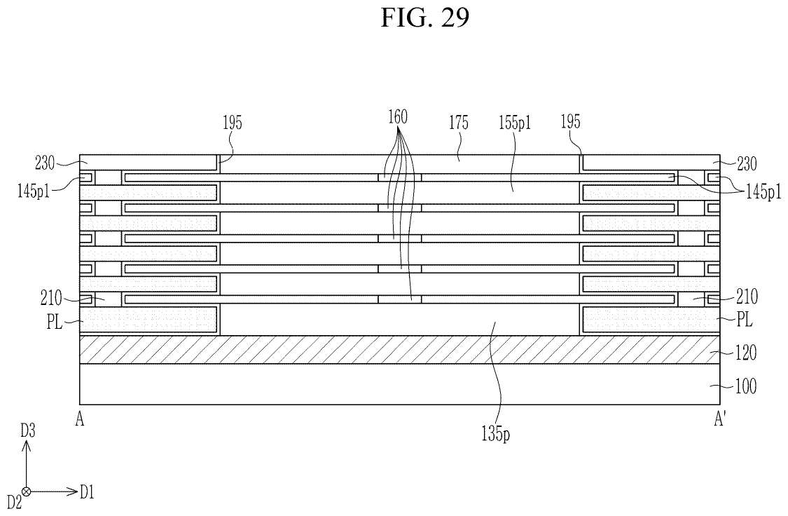

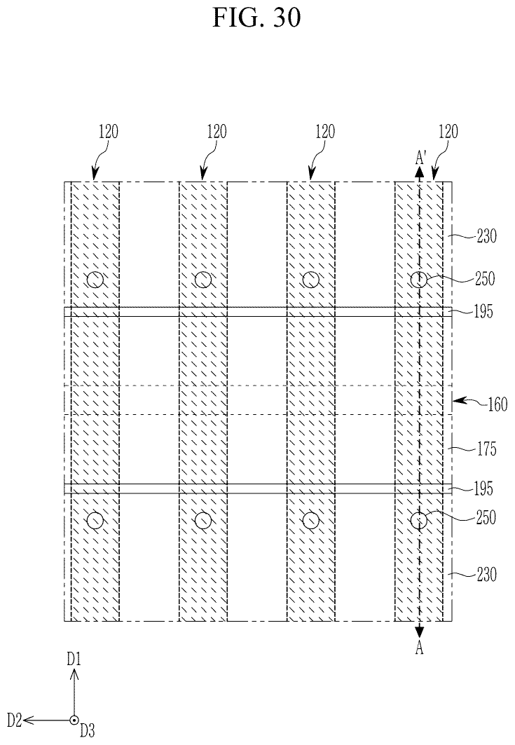

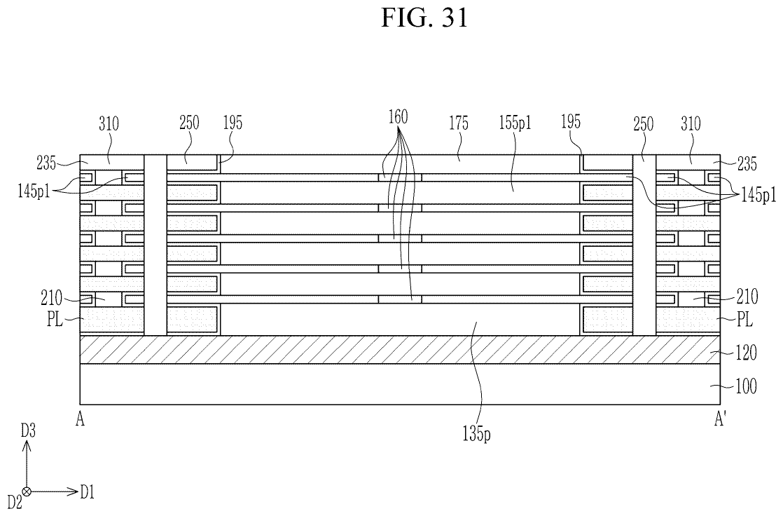

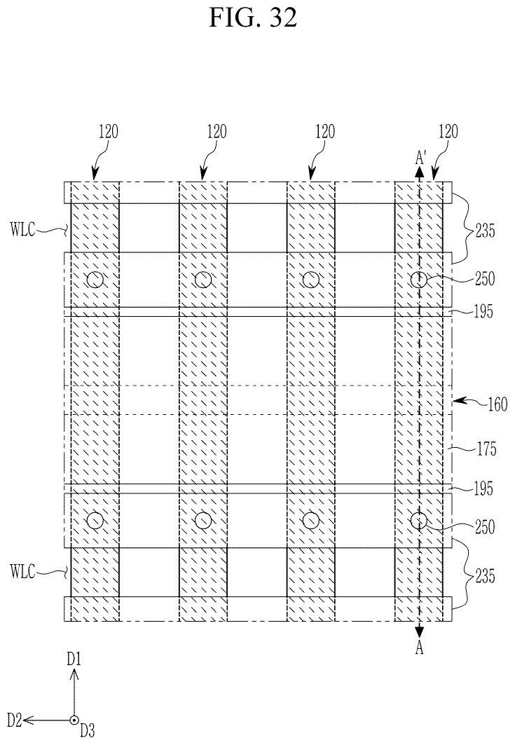

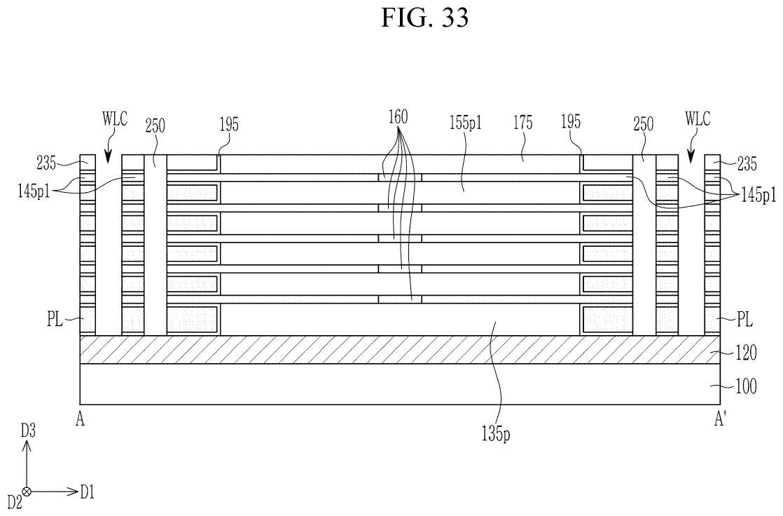

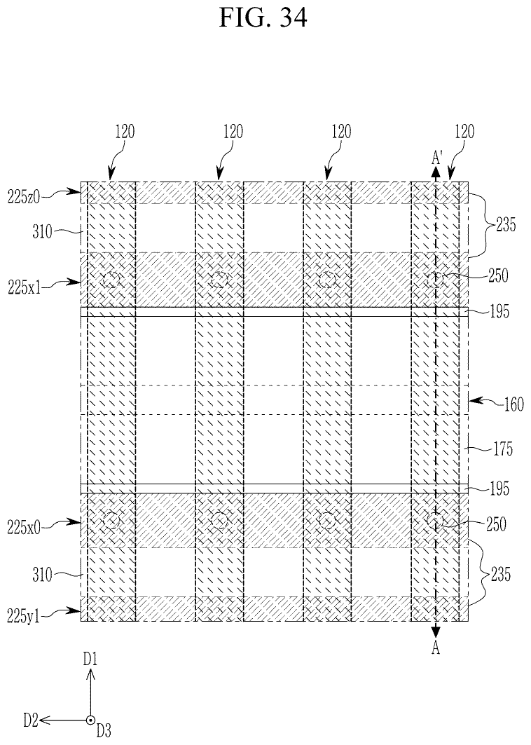

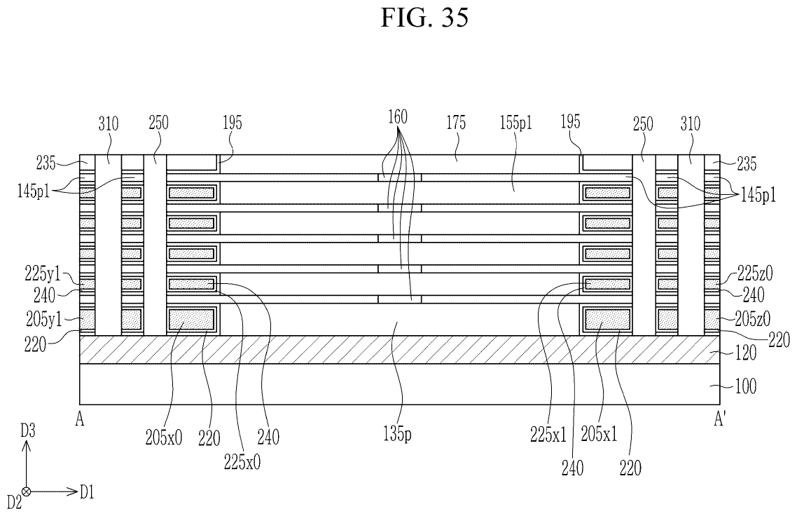

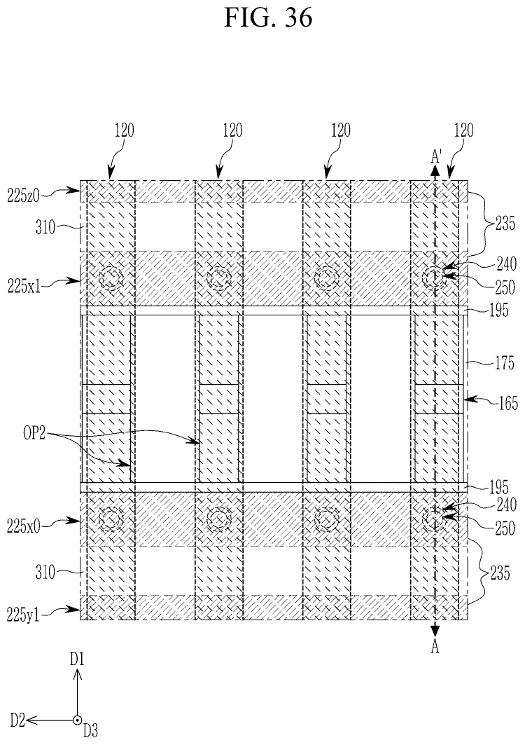

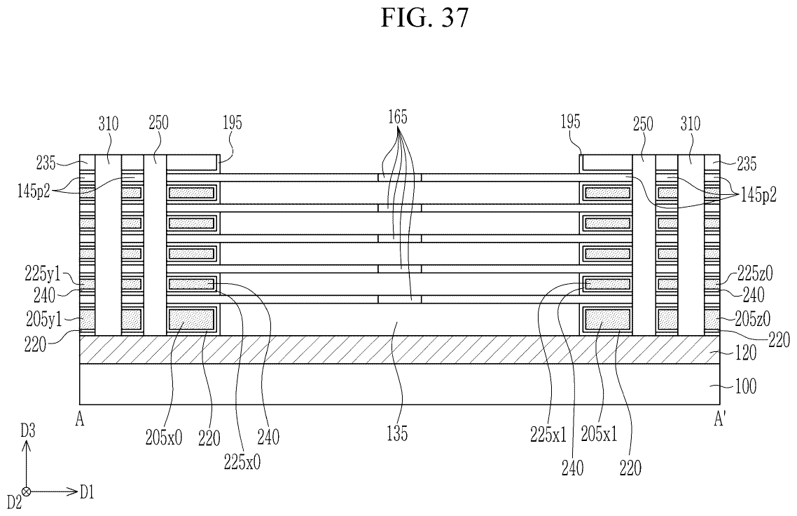

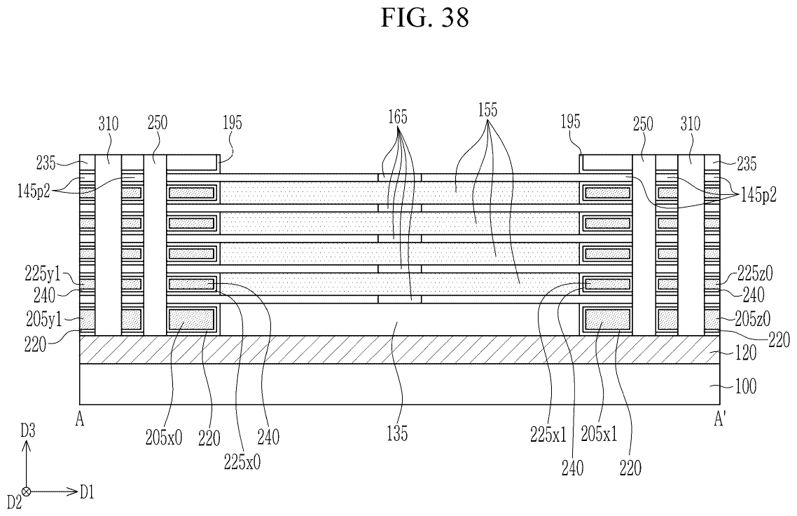

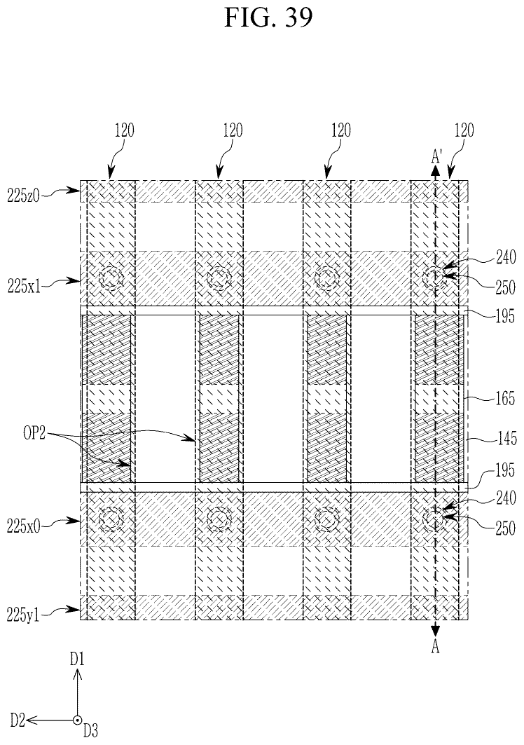

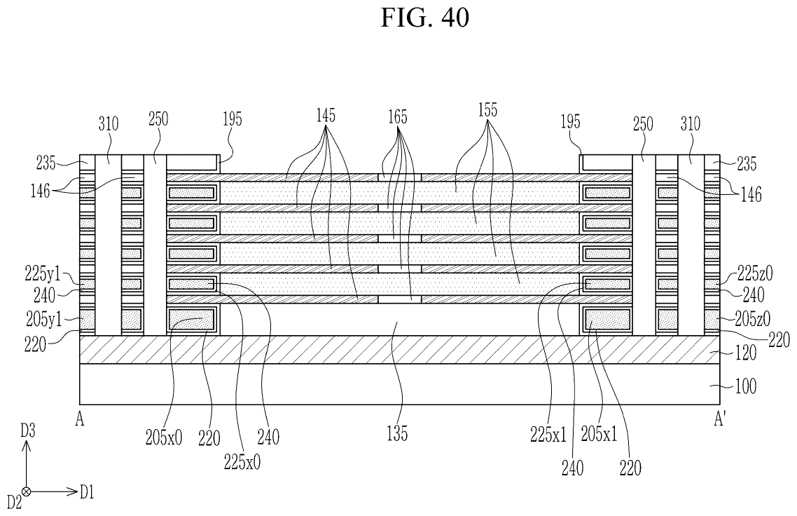

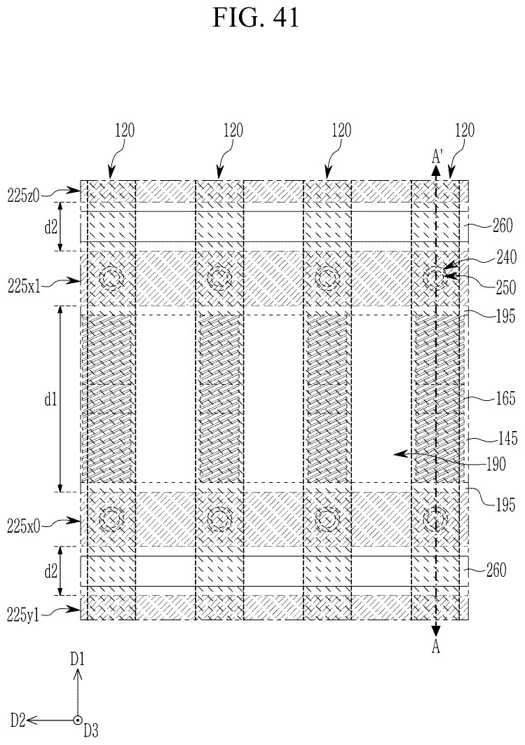

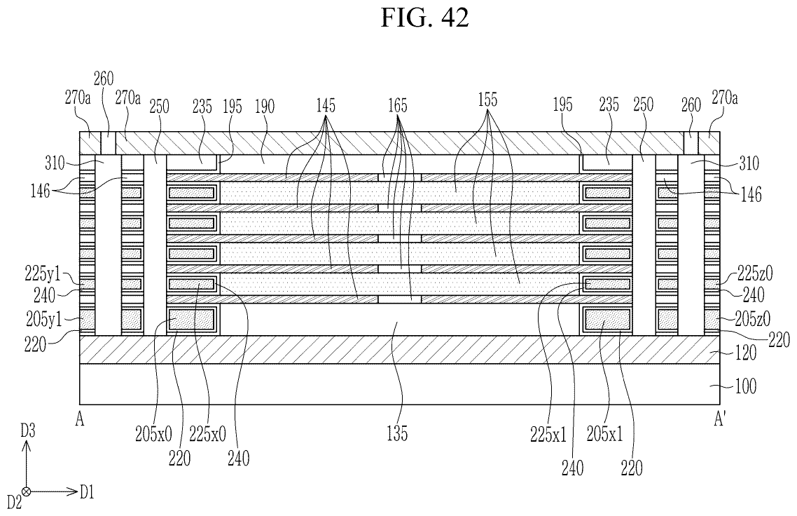

FIG. 20 to FIG. 42 are views for explaining a manufacturing method of a three-dimensional ferroelectric memory device according to one or more implementations. Specifically, FIG. 20, FIG. 22, FIG. 24, FIG. 26, FIG. 28, FIG. 30, FIG. 32, FIG. 34, FIG. 36, FIG. 39, and FIG. 41 are plan views. FIG. 21, FIG. 23, FIG. 25, FIG. 27, FIG. 29, FIG. 31, FIG. 33, FIG. 35, FIG. 37, FIG. 38, FIG. 40, and FIG. 42 are cross-sectional views taken along a line A-A′ of the corresponding plan views, respectively.

Referring to FIG. 20 and FIG. 21, after forming a lower layer 110 on a substrate 100, a bit line 120 penetrating therethrough may be formed on the substrate 100. According to the implementation, the lower layer 110 may include an insulating material.

According to one or more implementations, the bit lines 120 may extend in the first direction D1 and may be arranged in plural spaced apart from each other along the second direction D2.

Additionally referring to FIG. 22 and FIG. 23, after forming a lower insulation layer 130 on the lower layer 110 and the bit line 120, a first layer 140 and a second layer 150 may be alternately and repeatedly stacked along the third direction D3 on the lower insulation layer 130, and the first layer 140 may be laminated on the top layer. Next, a third layer 170 may be stacked on the first layer 140.

The first layer 140 may include a separation layer 160 extending in the second direction D2, and the first layer 140 may be separated in the first direction D1 by the separation layer 160.

According to the implementation, the first layer 140 may include an oxide such as silicon oxide, the second layer 150 may include an insulating polysilicon, and the separation layer 160 may include an insulating nitride such as silicon nitride, but is not limited thereto.

Additionally referring to FIG. 24 and FIG. 25, a dry etching process and a chemical etching process may be performed on the lower insulation layer 130, the first layer 140, the second layer 150, and the third layer 170 so that a first opening OP1 that penetrates them and exposes the upper surface of the substrate 100 and the bit line 120 may be formed. Through the etching step, the lower insulation layer 130, the first layer 140, the second layer 150, and the third layer 170 may be replaced with a preliminary lower insulating pattern 135p, a first/first preliminary pattern 145p1, a second/first preliminary pattern 155p1, and an upper pattern 175, respectively.

According to the implementation, an isotropic etching may be performed by utilizing an etch selectivity for the lower insulation layer 130 and the second layer 150 in the etching step, and a recess may be formed between the first/first preliminary patterns 145p1 adjacent in the third direction D3. Accordingly, the side wall of the first/first preliminary pattern 145p1 in the first direction D1 may be arranged to protrude relative to the side wall of the preliminary lower insulating pattern 135p and the second/first preliminary pattern 155p1 in the first direction D1.

The first opening OP1 may be extended in the second direction D2 to expose the upper surface of the substrate 100 and the upper surface of the bit line 120, and may be formed in multiple pieces spaced apart from each other along the first direction D1.

As the first opening OP1 is formed, the preliminary lower insulating pattern 135p, the first/first preliminary pattern 145p1, the second/first preliminary pattern 155p1, and the upper pattern 175 may each be formed in multiple pieces spaced apart from each other in the first direction D1.

Additionally referring to FIG. 26 and FIG. 27, an insulating layer 195 is formed along the side wall of the preliminary lower insulating pattern 135p, the protruded portion of the first/first preliminary pattern 145p1, the side wall of the second/first preliminary pattern 155p1, the bit line 120, and the upper surface of the substrate 100.

The insulating layer 195 may be a material selected from silicon, silicon oxide, silicon carbide, and silicon nitride, and may have a material different from the first/first preliminary pattern 145p1 and the second/first preliminary pattern 155p1. According to the implementation, the insulating layer is disposed via a thin film deposition process, which includes a chemical vapor deposition (CVD), an atomic layer deposition (ALD), etc. but is not limited to

Although the insulating layer 195 is not arranged on the upper surface of the upper pattern 175 in the drawing, this is not limited thereto, and the insulating layer 195 may be formed on the upper surface of the upper pattern 175 according to the deposition step according to the implementation.

Additionally referring to FIG. 28 and FIG. 29, a sacrificial layer PL and a fifth insulating pattern 210 may be alternately stacked on the upper surface of the substrate 100 and the bit line 120 exposed through the first opening OP1. Afterwards, an upper insulation layer 230 may be formed on the uppermost fifth insulating pattern 210 and the uppermost first/first preliminary pattern 145p1.

The sacrificial layer PL may be arranged between the side walls of the preliminary lower insulating pattern 135p in the first direction D1 and the side walls of the second/first preliminary pattern 155p1 in the first direction D1, and may be arranged in the recess between the first/first preliminary patterns 145p1 adjacent in the third direction D3. The fifth insulating pattern 210 may be arranged on the sacrificial layer (PL) and may be arranged between the side walls of the first/first preliminary pattern 145p1. in the first direction D1

The sacrificial layer PL is a material selected from among silicon, silicon oxide, silicon carbide, and silicon nitride, and may be a different material from the insulating layer 195.

Additionally referring FIG. 30 and FIG. 31, a channel 250 that is in contact with the upper surface of the bit line 120 and penetrates the upper insulation layer 230, the insulating layer 195, the first/first preliminary pattern 145p1, and the sacrificial layer PL may be formed.

Forming the corresponding channel 250 may include forming a channel hole penetrating the upper insulation layer 230, the insulating layer 195, the first/first preliminary pattern 145p1, and the sacrificial layer PL to exposed the upper surface of the bit line 120.

Additionally referring FIG. 32 and FIG. 33, a word line cut WLC may be formed by etching the upper insulation layer 230, the insulating layer 195, the first/first preliminary pattern 145p1, and the sacrificial layer PL to penetrate them and expose the upper surface of the substrate 100 and the bit line 120. Through the etching step, the upper insulation layer 230 may be replaced with a third insulating pattern 235, and the first/first preliminary pattern 145p1 may be separated in the first direction D1 to be formed in plural.

The word line cut WLC may be extended in the second direction D2 to expose the upper surface of the substrate 100 and the upper surface of the bit line 120, and may be formed in multiple pieces spaced apart from each other along the first direction D1. The word line cut WLC may be formed to be aligned with the fifth insulating pattern 210 in a flat area, and the fifth insulating pattern 210 may be removed according to the formation of the word line cut. Accordingly, the word line cut WLC may be formed further away from the channel 250 in the first direction D1 with separation layer 160 as a reference.

Additionally referring to FIG. 34 and FIG. 35, the sacrificial layer PL is etched through the word line cut WLC, a gate insulating layer 220 and 240 and a plurality of conductive patterns 205x0, 205x1, 205y1, 205z0, 225x0, 225x1, 225y1, and 225z0 are formed, and a separation insulating layer 310 separating the plurality of conductive patterns 205x0, 205x1, 205y1, 205z0, 225x0, 225x1, 225y1, and 225z0 in the first direction D1 may be formed.

According to the implementation, an etching solution (e.g., phosphoric acid, etc.) may be inflowed during the etching of the sacrificial layer PL, and the sacrificial layer PL may be selectively etched while leaving the insulating layer 195. In the space where the sacrificial layer PL is removed, the gate insulating layers 220 and 240 and the plurality of conductive patterns 205x0, 205x1, 205y1, 205z0, 225x0, 225x1, 225y1, and 225z0 may be sequentially formed.

Forming the separation insulating layer 310 may include exposing the upper surfaces of the bit line 120 and the substrate 100 by penetrating the plurality of conductive patterns 205x0, 205x1, 205y1, 205z0, 225x0, 225x1, 225y1, and 225z0 stacked in the third direction D3 and forming the word line cut extending in the second direction D2.

Additionally referring to FIG. 36, a dry etching process may be performed for the preliminary lower insulating pattern 135p, the first/first preliminary pattern 145p1, the separation layer 160, the second/first preliminary pattern 155p1, and the upper pattern 175 to penetrate them and form a second opening OP2 exposing the upper surface of the substrate 100. Through the corresponding etching step, the preliminary lower insulating pattern 135p, the first/first preliminary pattern 145p1, and the separation layer 160 may be replaced with the lower insulating pattern 135, the first/second preliminary pattern 145p2, and the separation pattern 165, respectively.

The second opening OP2 may be extended in the first direction D1 to expose the upper surface of the substrate 100, and may be formed in multiple pieces spaced apart from each other along the second direction D2.

As the second opening OP2 is formed, the lower insulating pattern 135, the first/second preliminary pattern 145p2, and the separation pattern 165 may each be formed in multiple pieces spaced apart from each other in the second direction D2.

Additionally referring to FIG. 37, a part of the second/first preliminary pattern 155p1 and the upper pattern 175 may be etched through the second opening OP2. Although not shown, through the corresponding etching, the second/first preliminary pattern 155p1 may be replaced with the second insulating pattern 156 of FIG. 1. In the corresponding etching, the second/first preliminary pattern 155p1, which is arranged in the space between the adjacent first/second preliminary patterns 145p2 in the third direction D3, may be etched.

According to one or more implementations, the etching solution may be inflowed in etching the part of the second/first preliminary pattern 155p1 and the upper pattern 175, the lower insulating pattern 135, the first/second preliminary pattern 145p2, and the separation pattern 165 may remain, and the portion of the second/first preliminary pattern 155p1 and the upper pattern 175 may be etched.

Additionally referring to FIG. 38, a ferroelectric pattern 155 may be formed through the second opening OP2. According to the implementation, the ferroelectric pattern 155 may be inflowed into the space from which the second/first preliminary pattern 155p1 is removed, and may be arranged in the space between the first/second preliminary patterns 145p2 adjacent in the third direction D3 and the separation patterns 165 adjacent in the third direction D3.

Additionally referring to FIG. 39 and FIG. 40, the part of the first/second preliminary pattern 145p2 may be etched through the second opening OP2, and the capacitor electrode 145 may be formed. As the portion of the first/second preliminary pattern 145p2 is etched, the first/second preliminary pattern 145p2 may be replaced with the first insulating pattern 146.

According to the implementation, in etching the part of the first/second preliminary pattern 145p2, the first/second preliminary patterns 145p2 may be etched in the space between the ferroelectric patterns 155 adjacent in the third direction D3 and in the space between the plurality of conductive patterns 205x0, 205x1, 205y1, 205z0, 225x0, 225x1, 225y1, and 225z0 adjacent in the third direction D3. According to the implementation, the etching solution may be inflowed through the second opening OP2, and the lower insulating pattern 135, the ferroelectric pattern 155, the separation pattern 165, and the insulating layer 195 may be left, and the part of the first/second preliminary pattern 145p2 may be selectively etched.

In the space where the first/second preliminary pattern 145p2 is removed, a conductive material may inflow to form a capacitor electrode 145.

Additionally referring to FIG. 41 and FIG. 42, the interlayer insulating layer 190 and the plate line 270a may be formed.

An interlayer insulating layer 190 covering the second opening OP2, the capacitor electrode 145, and the separation pattern 165 may be formed, and a plate line 270a may be formed on the upper surfaces of the interlayer insulating layer 190, the insulating layer 195, the third insulating pattern 235, the separation insulating layer 310, and the channel 250.

Through the sharing structure for the ferroelectric pattern 155 between the memory cell strings adjacent in the first direction D1, the manufacturing process of the three-dimensional ferroelectric memory device 10a may be performed while separating the first/second and second/second conductive patterns 225x0 and 225x1 from the ferroelectric pattern 155 and the capacitor electrode 145. The manufacturing method of the three-dimensional ferroelectric memory device 10a may easily improve the electric characteristics without performing a separate manufacturing process to suppress the influence of parasitic capacitors.

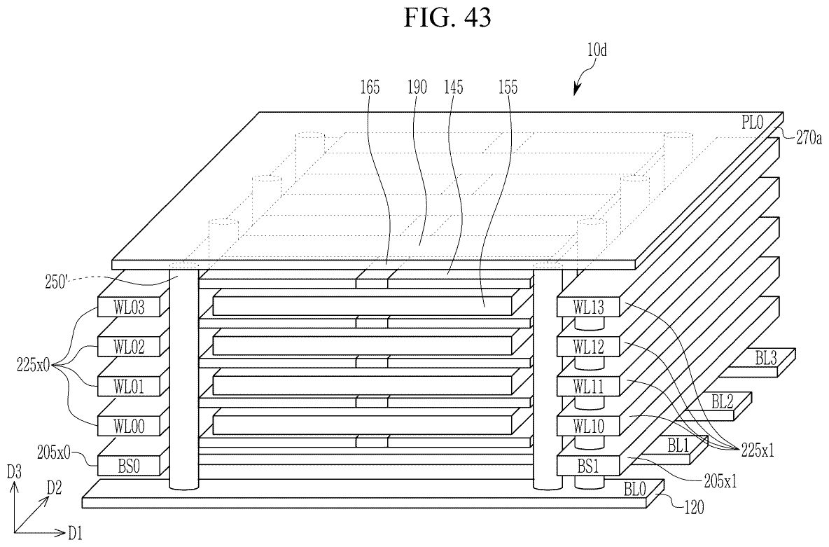

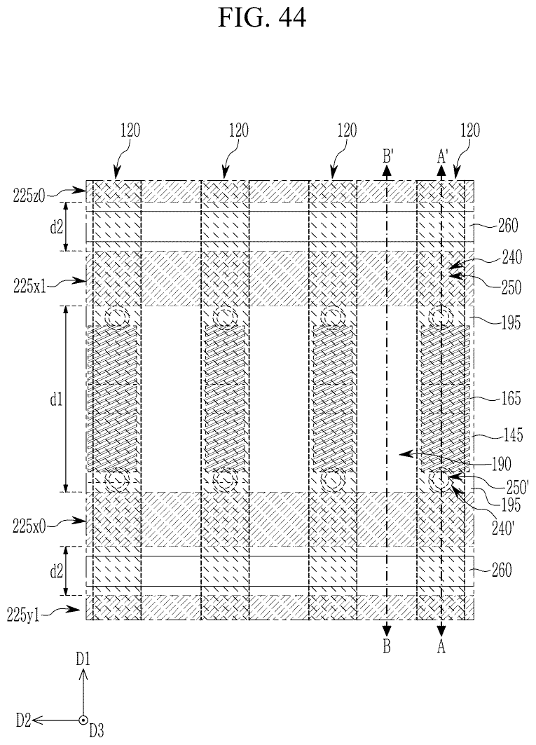

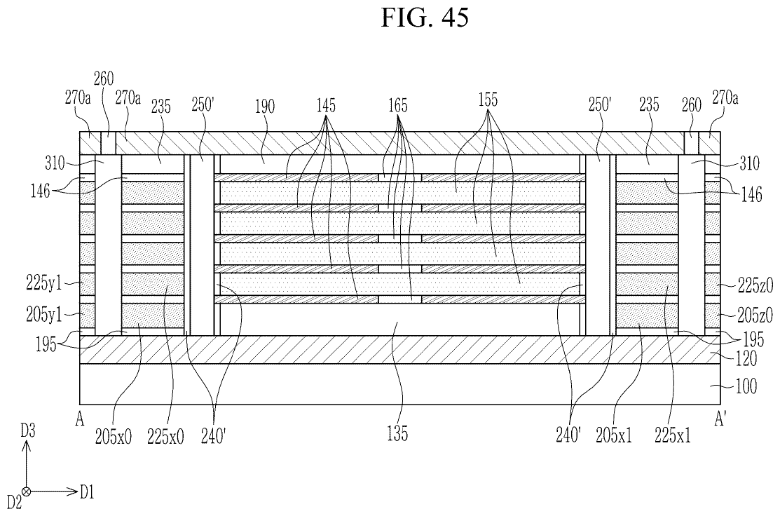

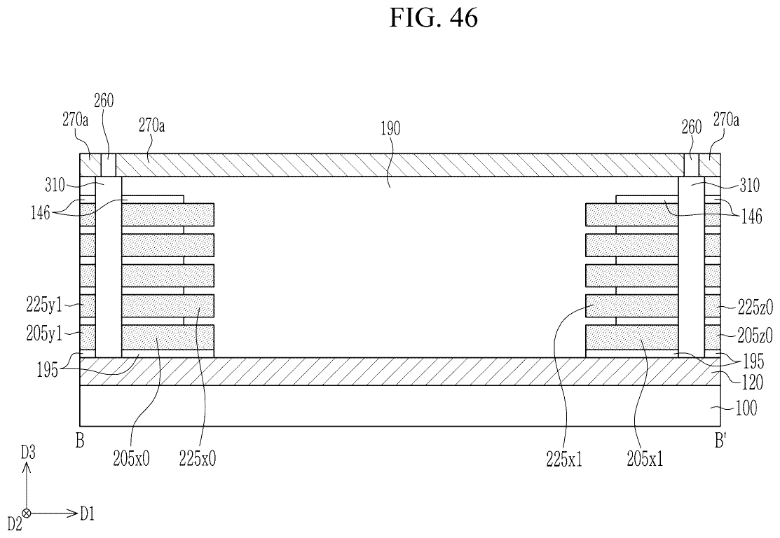

FIG. 43 is a perspective view showing a cell region of a three-dimensional ferroelectric memory device according to one or more implementations. FIG. 44 is a top plan view showing a cell region of a three-dimensional ferroelectric memory device according to one or more implementations. FIG. 45 is a cross-sectional view taken along a line A-A′ of FIG. 44. FIG. 46 is a cross-sectional view taken along a line B-B′ of FIG. 44. Specifically, FIG. 44 is the top plan view showing some regions within the three-dimensional ferroelectric memory device 10d.

The three-dimensional ferroelectric memory device 10d of FIG. 43 to FIG. 46 may correspond to the three-dimensional ferroelectric memory device 10a of FIG. 1 to FIG. 6. For ease of explanation, redundant descriptions are omitted below and the three-dimensional ferroelectric memory device 10d is described focusing on the differences from the three-dimensional ferroelectric memory device 10a of FIG. 1 to FIG. 6.

Referring to FIG. 43 to FIG. 46, a channel 250′ of the three-dimensional ferroelectric memory device 10d may be arranged adjacent to one side wall of the first/first and first/second conductive patterns 205x0 and 225x0 and the second/first and second/second conductive patterns 205x1 and 225x1 in the first direction D1 without penetrating the first/first and first/second conductive patterns 205x0 and 225x0 and the second/first and second/second conductive patterns 205x1 and 225x1.

In this case a gate insulating layer 240′ may be interposed between the first/first and first/second conductive patterns 205x0 and 225x0 and the channel 250′, and between the second/first and second/second conductive patterns 205x1 and 225x1 and the channel 250′.

The gate insulating layer 240′ may extend along the channel 250′ in the third direction D3 and surround the channel 250′ according to the height in the third direction D3. According to the implementation, the gate insulating layer 240′ may surround the channel 250′ at the height where the ferroelectric pattern 155 is arranged. According to the implementation, at a height at which the capacitor electrode 145 is placed, the capacitor electrode 145 and the gate insulating layer 240′ may be in contact with the channel 250′.

The insulating layer 195 may be arranged on the bit line 120 and the substrate 100 and may extend in the second direction D2, and may be formed in a plurality of pieces spaced apart from each other along the first direction D1 or separated from each other by the separation insulating layer 310. Each insulating layer 195 may be arranged along the upper surface of the bit line 120 and the substrate 100.

The insulating layer 195 may be interposed between the bit line 120 and the first/first conductive pattern 205x0, and between the bit line 120 and the second/first conductive pattern 205x1. Through the insulating layer 195, the bit line 120 and the plurality of conductive patterns 205x0, 205x1, 205y1, 205z0, 225x0, 225x1, 225y1, and 225z0 may be electrically isolated. According to one or more implementations, the insulating layer 195 may extend in the third direction D3 along one side wall of the channel 250′ or the plurality of conductive patterns 205x0, 205x1, 205y1, 205z0, 225x0, 225×1, 225y1, and 225z0.

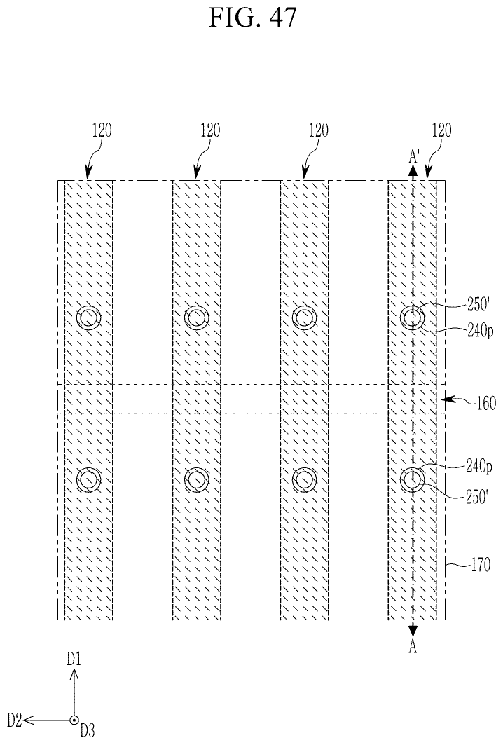

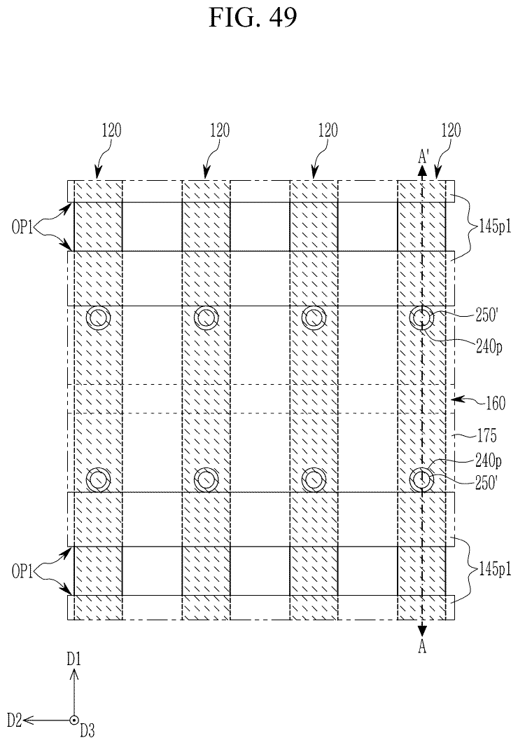

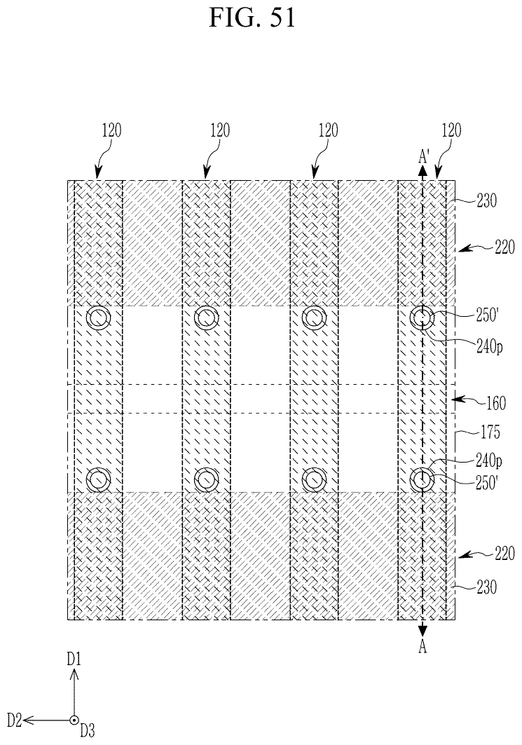

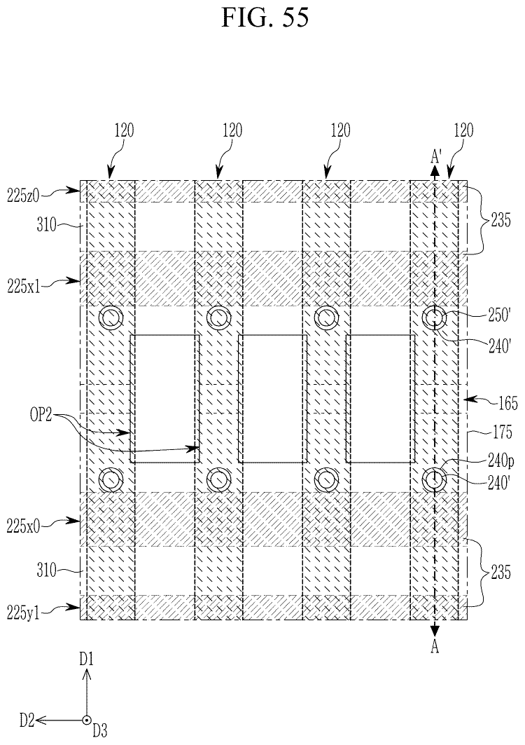

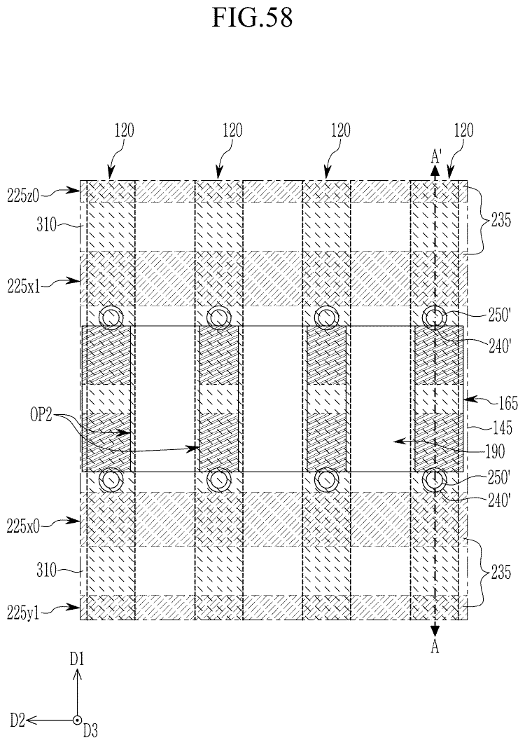

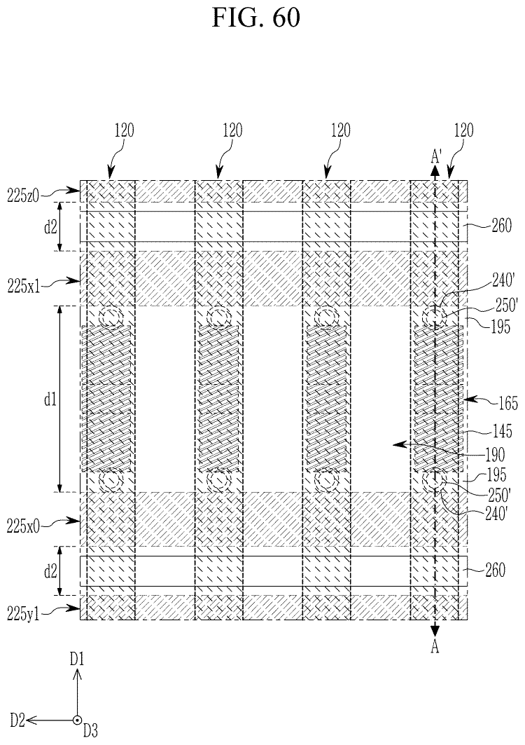

FIG. 47 to FIG. 61 are views for explaining a manufacturing method of a three-dimensional ferroelectric memory device according to one or more implementations. Specifically, FIG. 47, FIG. 49, FIG. 51, FIG. 55, FIG. 58, and FIG. 60 are plan views. FIG. 21, FIG. 23, FIG. 25, FIG. 27, FIG. 29, FIG. 31, FIG. 33, FIG. 35, FIG. 37, FIG. 38, FIG. 40, and FIG. 42 are cross-sectional views taken along a line A-A′ of the corresponding plan views, respectively.

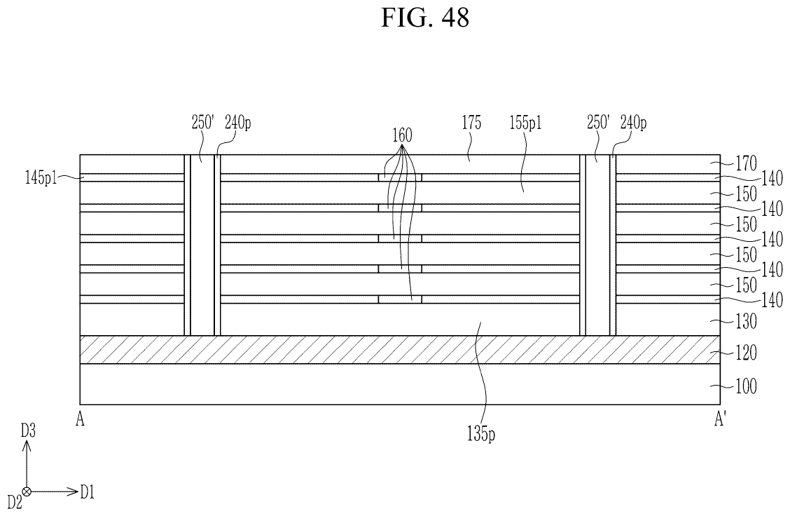

Before performing the steps of FIG. 47 and FIG. 48, the steps of FIG. 20 to FIG. 23 may be performed first. Referring to FIG. 47 and FIG. 48, after performing the steps of FIG. 20 to FIG. 23, a preliminary gate insulating layer 240p and a channel 250′ may be sequentially formed to be in contact with the upper surface of the bit line 120 and penetrate the lower insulation layer 130, the first layer 140, the second layer 150, and the third layer 170.

According to the implementation, the preliminary gate insulating layer 240p may include the same material as the first layer 140, as a material selected from silicon, silicon oxide, silicon carbide, and silicon nitride.

Forming the channel 250 may include forming a channel hole penetrating the lower insulation layer 130, the first layer 140, the second layer 150, and the third layer 170 to expose the upper surface of the bit line 120.

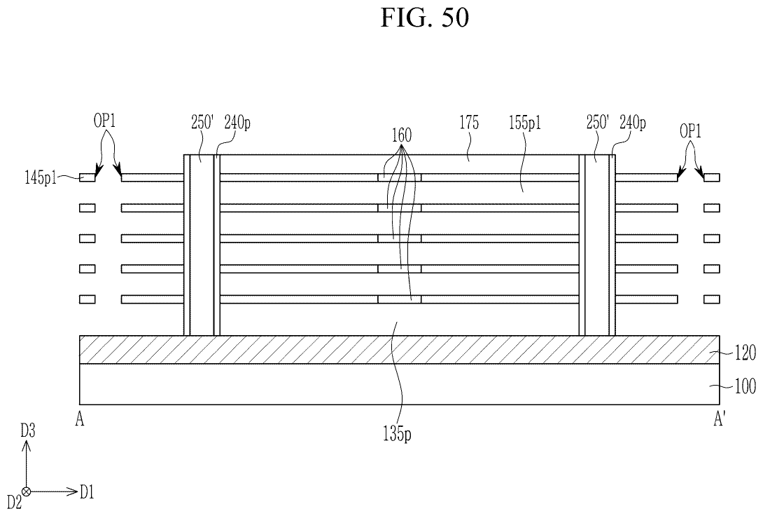

Additionally referring to FIG. 49 and FIG. 50, a dry etching process and a chemical etching process may be performed on the lower insulation layer 130, the first layer 140, the second layer 150, and the third layer 170, so that a first opening OP1 penetrating them and exposing the upper surface of the substrate 100 and the bit line 120 may be formed. Through the etching, the lower insulation layer 130, the first layer 140, the second layer 150, and the third layer 170 may be replaced with the preliminary lower insulating pattern 135p, the first/first preliminary pattern 145p1, the second/first preliminary pattern 155p1, and the upper pattern 175, respectively.

According to the implementation, an isotropic etching may be performed by utilizing an etch selectivity for the lower insulation layer 130 and the second layer 150 in the corresponding etching, and a recess may be formed between the first/first preliminary patterns 145p1 adjacent in the third direction D3. Accordingly, the side wall of the first/first preliminary pattern 145p1 in the first direction D1 may be arranged to protrude relative to the side wall of the preliminary lower insulating pattern 135p and the second/first preliminary pattern 155p1 in the first direction D1.

The first opening OP1 may be extended in the second direction D2 to expose the upper surface of the substrate 100 and the upper surface of the bit line 120, and may be formed in multiple pieces spaced apart from each other along the first direction D1.

As the first opening OP1 is formed, the preliminary lower insulating pattern 135p, the first/first preliminary pattern 145p1, the second/first preliminary pattern 155p1, and the upper pattern 175 may each be formed in multiple pieces spaced apart from each other in the first direction D1. According to the implementation, the first opening OP1 may be formed at a location further away from the channel 250′ in the first direction D1 with the separation layer 160 as a reference.

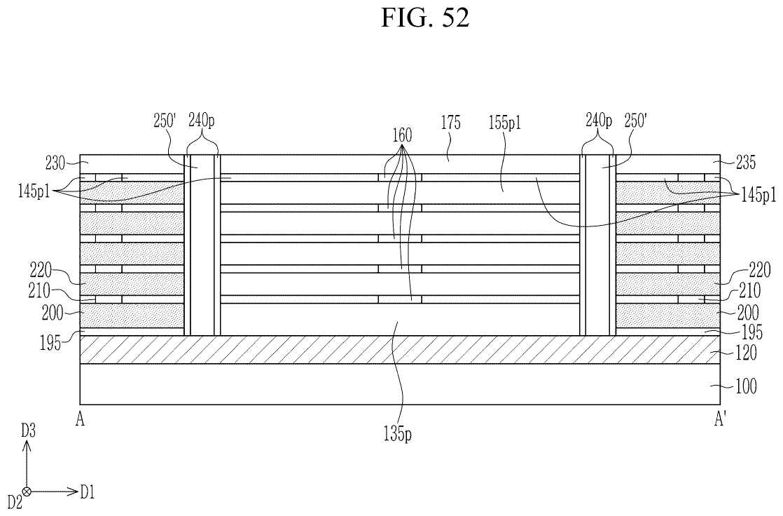

Additionally referring to FIG. 51 and FIG. 52, an insulating layer 195 may be formed on the upper surface of the substrate 100 and the bit line 120 exposed through the first opening OP1, and a preliminary conductive pattern 200, 220, and a fifth insulating pattern 210 may be alternately stacked on the insulating layer 195. Next, an upper insulation layer 230 may be formed on the uppermost fifth insulating pattern 210 and the uppermost first/first preliminary pattern 145p1.

The insulating layer 195 may be arranged along the upper surface of the exposed substrate 100 and the upper surface of the bit line 120. The first preliminary conductive pattern 200 may be arranged along the side wall of the preliminary lower insulating pattern 135p and the side wall of the preliminary gate insulating layer 240p in the first direction D1 on the insulating layer 195.

The second preliminary conductive pattern 220 may be arranged along the side wall of the second/first preliminary pattern 155p1 and the side wall of the preliminary gate insulating layer 240p in the first direction D1, and may be arranged in the recess between the first/first preliminary patterns 145p1 adjacent in the third direction D3. The fifth insulating pattern 210 may be arranged on the preliminary conductive patterns 200 and 220 and may be placed between the side walls of the first/first preliminary pattern 145p1 in the first direction D1.

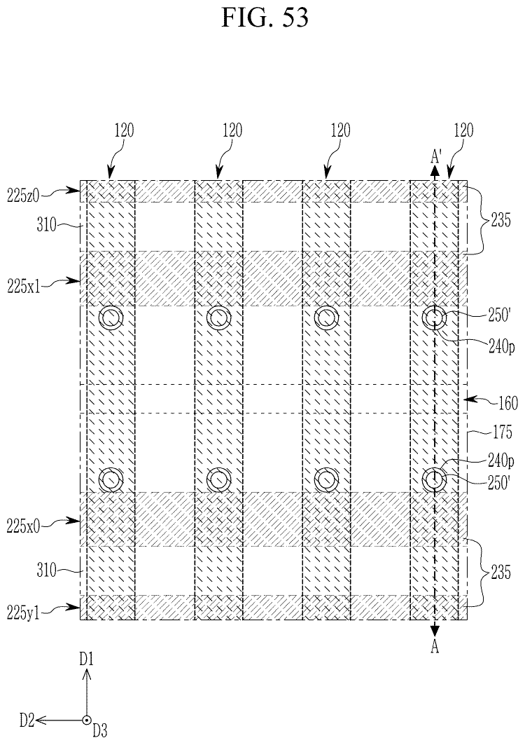

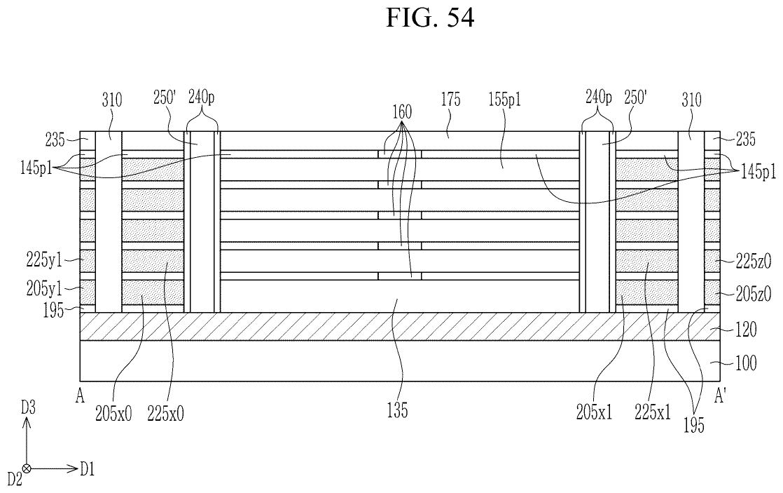

Additionally referring to FIG. 53 and FIG. 54, a separation insulating layer 310 that separates the plurality of conductive patterns 205x0, 205x1, 205y1, 205z0, 225×0, 225x1, 225y1, and 225z0 in the first direction D1 is formed.

Forming the separation insulating layer 310 may include forming a word line cut penetrating the preliminary conductive patterns 200 and 220 stacked in the third direction D3 to expose the upper surface of the bit line 120 and the substrate 100 and extending in the second direction D2. The word line cut may be formed to be aligned with the fifth insulating pattern 210 in a flat area, and the fifth insulating pattern 210 may be removed according to the formation of the word line cut.

Additionally referring to FIG. 55, a dry etching process may be performed for the preliminary lower insulating pattern 135p, the first/first preliminary pattern 145p1, the separation layer 160, the second/first preliminary pattern 155p1, and the upper pattern 175 to form a second opening OP2 penetrating them and exposing the upper surface of the substrate 100. Through the etching, the preliminary lower insulating pattern 135p, the first/first preliminary pattern 145p1, and the separation layer 160 may be replaced with the lower insulating pattern 135, the first/second preliminary pattern 145p2, and the separation pattern 165, respectively.

The second opening OP2 may be extended in the first direction D1 to expose the upper surface of the substrate 100, and may be formed in plural to spaced apart from each other along the second direction D2. As the second opening OP2 is formed, the separation pattern 165 may be formed multiple to be separated from each other in the second direction D2.

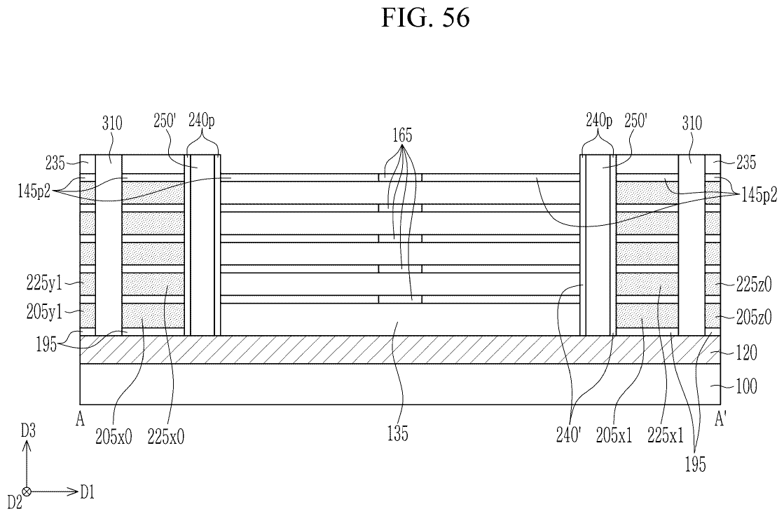

Additionally referring to FIG. 56, the part of the second/first preliminary pattern 155p1 and the upper pattern 175 may be etched through the second opening OP2. Although not shown, through the etching, the second/first preliminary pattern 155p1 may be replaced with the second insulating pattern 156 of FIG. 1. In the etching, the second/first preliminary pattern 155p1, which is arranged in the space between the first/second preliminary patterns 145p2 adjacent in the third direction D3, may be etched.

According to the implementation, an etching solution may be inflowed during the etching of the part of the second/first preliminary pattern 155p1 and the upper pattern 175, and the lower insulating pattern 135, the first/second preliminary pattern 145p2, and the separation pattern 165 may be left, and the part of the second/first preliminary pattern 155p1 and the upper pattern 175 may be selectively etched.

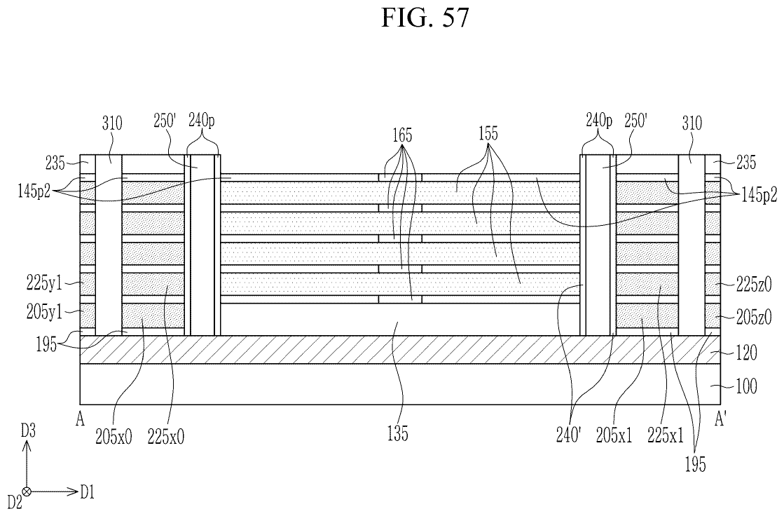

Additionally referring to FIG. 57, the ferroelectric pattern 155 may be formed through the second opening OP2. According to the implementation, the ferroelectric pattern 155 may be inflowed into the space from which the second/first preliminary pattern 155p1 is removed, and may be arranged in the space between the first/second preliminary patterns 145p2 adjacent in the third direction D3 and the separation patterns 165 adjacent in the third direction D3.

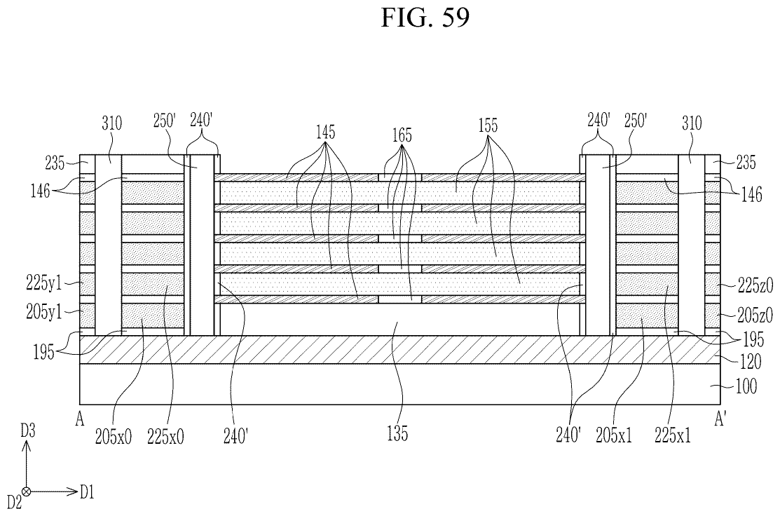

By referring to FIG. 58 and FIG. 59, the part of the first/second preliminary pattern 145p2 and the part of the preliminary gate insulating layer 240p may be etched through the second opening OP2, and the capacitor electrode 145 may be formed. The portion of the etched preliminary gate insulating layer 240p may be a region located at the same height as the first/second preliminary pattern 145p2 and may come into contact with the first/second preliminary pattern 145p2 before the etching. As the portions of the preliminary gate insulating layer 240p and the first/second preliminary pattern 145p2 are etched, the first/second preliminary pattern 145p2 and the preliminary gate insulating layer 240p may be replaced with the first insulating pattern 146 and the gate insulating layer 240p′, respectively.

According to the implementation, in etching the part of the first/second preliminary pattern 145p2 and the part of the preliminary gate insulating layer 240p, the first/second preliminary patterns 145p2 may be etched in the space between the ferroelectric patterns 155 adjacent in the third direction D3 and in the space between the plurality of conductive patterns 205x0, 205x1, 205y1, 205z0, 225x0, 225x1, 225y1, and 225z0 adjacent in the third direction D3. According to the implementation, the etching solution may be inflowed through the second opening OP2, the lower insulating pattern 135, the ferroelectric pattern 155, the separation pattern 165, and the insulating layer 195 remain, and the portion of the first/second preliminary pattern 145p2 and the portion of the preliminary gate insulating layer 240p in contact with the first/second preliminary pattern 145p2 may be selectively etched.

In the space where the first/second preliminary pattern 145p2 and the preliminary gate insulating layer 240p are removed, a conductive material may inflow to form the capacitor electrode 145.

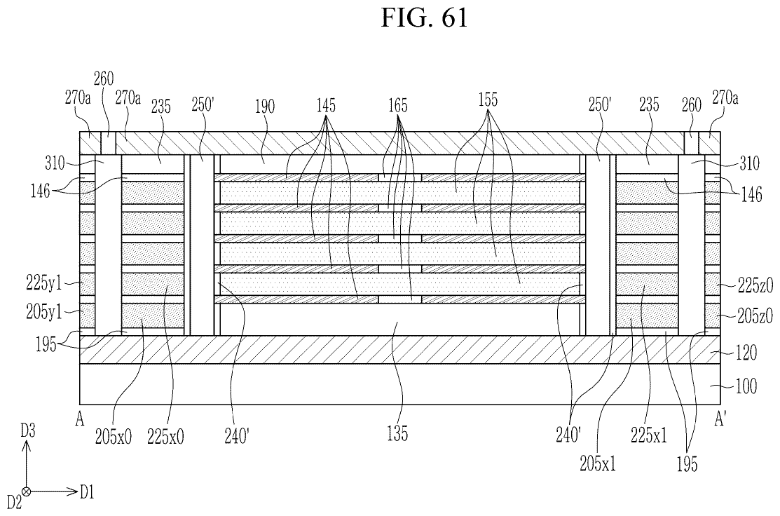

Additionally reference to FIG. 60 and FIG. 61, an interlayer insulating layer 190 and a plate line 270a may be formed.

The interlayer insulating layer 190 covering the second opening OP2, capacitor electrode 145, and separation pattern 165 may be formed, and the plate line 270a can be formed on the upper surface of the interlayer insulating layer 190, the insulating layer 195, the third insulating pattern 235, the separation insulating layer 310, the gate insulating layer 240′, and the channel 250′.

Through the sharing structure for the ferroelectric pattern 155 between the memory cell strings adjacent in the first direction D1, the manufacturing process of the three-dimensional ferroelectric memory device 10d may be performed while separating the first/second and second/second conductive patterns 225x0 and 225x1 from the ferroelectric pattern 155 and the capacitor electrode 145. The manufacturing method of the three-dimensional ferroelectric memory device 10d may easily improve the electric characteristics without performing a separate manufacturing process to suppress the influence of parasitic capacitors.

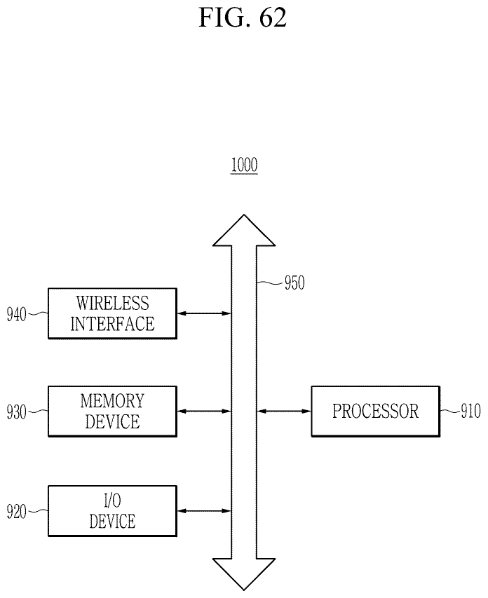

FIG. 62 is a block diagram showing an electronic device according to one or more implementations.

Referring to FIG. 62, an electronic device 1000 may include a PDA, a laptop computer, a portable computer, a web tablet, a wireless phone, a mobile phone, a digital music player, a wired/wireless electronic device, etc., but is not limited thereto. The electronic device 1000 may include a processor 910, an input/output device (920, e.g., a keypad, a keyboard and/or a display), a memory device 930, and a wireless interface 940.

The processor 910 may be implemented as a hardware-like processing circuit including logic circuits, a hardware/software combination such as a processor execution software, or a combination thereof. For example, the processor 910 may more specifically include, but is not limited to, a central processing unit (CPU), a microprocessor, a digital signal processor, a micro controller or other logic device. For example, the processor 910 may more specifically include central processing unit (CPU), a microprocessor, a digital signal processor, a micro controller or other logic device, but is not limited thereto,. Other logic devices may have functions similar to those of a microprocessor, a digital signal processor, or a microcontroller.

The memory device 930 may store instructions to be executed by the processor 910, for example. Additionally, the memory device 930 may also be used to store a user data. The memory device 930 may include a plurality of memory cells. The plurality of memory cells may be the memory cells as described in FIG. 1 to FIG. 61 or may be manufactured using the steps described in FIG. 1 to FIG. 61, such that the memory device 930 may include the three-dimensional ferroelectric memory having improved electrical characteristics and integration.

The electronic device 1000 may use the wireless interface 940 to transmit a data to or receive a data from a wireless communication network that communicates with wireless frequency (RF) signals. For example, the wireless interface 940 may include an antenna or a wireless transceiver. The electronic device 1000 can be used for communication interface protocols such as third generation communication systems (e.g., CDMA, GSM, NADC, E-TDMA, WCDMA and/or CDMA2000).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination.

Moreover, although features may be described above as acting in certain combinations, one or more features from a combination can in some cases be excised from the combination, and the combination may be directed to a subcombination or variation of a subcombination.

1. A three-dimensional ferroelectric memory device comprising:
a substrate;
a plurality of bit lines extending in a first direction on the substrate and spaced apart from each other in a second direction intersecting the first direction;
a first block selection line and a second block selection line each extending in the second direction over the plurality of bit lines and spaced apart from each other in the first direction;
a first word line that overlaps at least part of the first block selection line in a third direction orthogonal with the first direction and the second direction, and wherein the first word line extends in the second direction;
a second word line that overlaps at least part of the second block selection line in the third direction, is separated from the first word line in the first direction, and extends in the second direction;
a first channel extending in the third direction on a first bit line of the plurality of bit lines and positioned adjacent to the first block selection line and the first word line;
a second channel extending in the third direction on the first bit line of the plurality of bit lines and positioned adjacent to the second block selection line and the second word line;
a ferroelectric pattern arranged between the first channel and the second channel; and
a first capacitor electrode and a second capacitor electrode both arranged adjacent to the ferroelectric pattern in the third direction, between the first channel and the second channel, and separated from each other in the first direction by a separation pattern.

2. The three-dimensional ferroelectric memory device of claim 1, wherein:
the first capacitor electrode and the second capacitor electrode are in contact with a surface of the ferroelectric pattern.

3. The three-dimensional ferroelectric memory device of claim 2, wherein:
the separation pattern is in contact with the surface of the ferroelectric pattern.

4. The three-dimensional ferroelectric memory device of claim 1, wherein:
the first channel passes through the first word line and the first block selection line.

5. The three-dimensional ferroelectric memory device of claim 4, wherein:
at least a portion of the first word line is arranged to overlap the first capacitor electrode in the third direction.

6. The three-dimensional ferroelectric memory device of claim 5, comprising:
a first insulating layer at least partially surrounding the first word line,
wherein the first word line is separated from the first capacitor electrode and the ferroelectric pattern by the first insulating layer, and the first capacitor electrode is in contact with the first channel.

7. The three-dimensional ferroelectric memory device of claim 1, wherein:
the first channel is positioned adjacent to a side wall of the first block selection line and a side wall of the first word line.

8. The three-dimensional ferroelectric memory device of claim 1, further comprising:
a plate line in contact with an upper surface of the first channel.

9. The three-dimensional ferroelectric memory device of claim 8, wherein:
the plate line is in contact with an upper surface of the second channel.

10. The three-dimensional ferroelectric memory device of claim 2, wherein the ferroelectric pattern is a first ferroelectric pattern, and wherein the three-dimensional ferroelectric memory device comprises:
a second ferroelectric pattern arranged between the first channel and the second channel and spaced apart from the first ferroelectric pattern along the third direction,
wherein the second ferroelectric pattern is in contact with the first capacitor electrode and the second capacitor electrode.

11. The three-dimensional ferroelectric memory device of claim 1, further comprising:
a third word line separated from the first word line in the first direction and extending in the second direction,
wherein the first word line is between the second word line and the third word line in the first direction, and
a distance between the first word line and the second word line is different from a distance between the first word line and the third word line.

12. The three-dimensional ferroelectric memory device of claim 11, wherein:
the distance between the first word line and the second word line is greater than the distance between the first word line and the third word line.

13. The three-dimensional ferroelectric memory device of claim 12, comprising:
a separation insulating layer between the first word line and the third word line,
wherein the separation insulating layer extends along the second direction.

14. A three-dimensional ferroelectric memory device comprising:
a substrate;
a plurality of bit lines extending in a first direction on the substrate and spaced apart from each other in a second direction intersecting the first direction;
a first block selection line and a second block selection line each extending in the second direction over the plurality of bit lines and spaced apart from each other in the first direction;
a first word line that overlaps at least part of the first block selection line in a third direction orthogonal with the first direction and the second direction, and wherein the first word line extends in the second direction;
a second word line that overlaps at least part of the second block selection line in the third direction, is separated from the first word line in the first direction, and extends in the second direction;
a first channel extending in the third direction on a first bit line of the plurality of bit lines and positioned adjacent to the first block selection line and the first word line;
a second channel extending in the third direction on the first bit line of the plurality of bit lines and positioned adjacent to the second block selection line and the second word line;
a first capacitor electrode and a second capacitor electrode both arranged between the first channel and the second channel, the first capacitor electrode being separated from the second capacitor electrode in the first direction; and
a ferroelectric pattern in contact with the first capacitor electrode and the second capacitor electrode and arranged between the first channel and the second channel.

15. The three-dimensional ferroelectric memory device of claim 14, wherein:
the first capacitor electrode and the second capacitor electrode are separated in the first direction by a first separation pattern, and
the first capacitor electrode, the second capacitor electrode and the first separation pattern are in contact with a first surface of the ferroelectric pattern.

16. The three-dimensional ferroelectric memory device of claim 15, further comprising:
a third capacitor electrode and a fourth capacitor electrode separated in the first direction by a second separation pattern between the first channel and the second channel,
wherein the third capacitor electrode, the fourth capacitor electrode and the second separation pattern are in contact with a second surface of the ferroelectric pattern different from the first surface of the ferroelectric pattern,
the first capacitor electrode, the third capacitor electrode, and the ferroelectric pattern form a first capacitor, and
the second capacitor electrode, the fourth capacitor electrode, and the ferroelectric pattern form a second capacitor.

17. A three-dimensional ferroelectric memory device comprising:
a substrate;
a first bit line extending in a first direction on the substrate;
a first block selection line and a second block selection line extending in a second direction intersecting the first direction and spaced apart from each other in the first direction;
a first word line that overlaps at least part of the first block selection line in a third direction that is orthogonal to the first direction and the second direction, wherein the first word line extends in the second direction;
a second word line that overlaps at least part of the second block selection line in the third direction, is separated from the first word line in the first direction, and extends in the second direction;
a first cell string including a first block selection transistor controlled by the first block selection line, a first transistor controlled by the first word line, and a first capacitor coupled in parallel to the first transistor; and
a second cell string including a second block selection transistor controlled by the second block selection line, a second transistor controlled by the second word line, and a second capacitor coupled in parallel to the second transistor,
wherein the first capacitor and the second capacitor share a ferroelectric pattern.

18. The three-dimensional ferroelectric memory device of claim 17, further comprising:
a plate line spaced apart from the first bit line in the third direction,
wherein the first cell string is electrically connected to the first bit line and the plate line.

19. The three-dimensional ferroelectric memory device of claim 18, wherein:
the second cell string is electrically connected to the first bit line and the plate line.

20. The three-dimensional ferroelectric memory device of claim 19, wherein:
the first block selection transistor and the second block selection transistor are configured to operate in opposite states.

21. (canceled)
